(19) United States
(12) Patent Application Publication
(10) Pub. No.: US 2025/0098495 A1
(43) Pub. Date: Mar. 20, 2025

(54) DISPLAY PANEL, DISPLAY DEVICE, AND PERSONAL IMMERSION DEVICE INCLUDING THE SAME

(71) Applicant: LG Display Co., Ltd., Seoul (KR)

(72) Inventor: Yeon Suk KANG, Paju-si (KR)

(73) Assignee: LG Display Co., Ltd., Seoul (KR)

(21) Appl. No.: 18/750,583

(22) Filed: Jun. 21, 2024

(30) Foreign Application Priority Data
Sep. 18, 2023 (KR) 10-2023-0123917

(51) Int. Cl. H10K 59/80; G02B 27/01; H10K 59/18; H10K 59/38

(52) U.S. Cl. CPC H10K 59/879; G02B 27/0172; H10K 59/18; H10K 59/38; H10K 59/8792; G02B 2027/0112; G02B 2027/0178

(57) ABSTRACT

A display panel can include a first plurality of sub-pixels disposed on a substrate in a first display area, and a second plurality of sub-pixels disposed on the substrate in a second display area surrounding the first display area, a light emitting layer configured to emit light in each of the first plurality of sub-pixels and the second plurality of sub-pixels, a color filter layer disposed on the light emitting layer, and a plurality of condensing lenses disposed on the color filter layer in the second display area. Also, the plurality of condensing lenses are disposed to correspond one-to-one to emission areas of the second plurality of sub-pixels disposed in the second display area, and a central axis of each of the plurality of condensing lenses in the second display area is misaligned with a central axis of a corresponding emission area among the emission areas.

### CROSS-REFERENCE TO RELATED APPLICATION

This application claims priority to Korean Patent Application No. 10-2023-0123917 filed in the Republic of Korea on Sep. 18, 2023, the entirety of which is incorporated herein by reference into the present application.

### BACKGROUND

### Field of the Invention

The present specification relates to a display panel, a display device, and a personal immersion device including the same.

### Discussion of the Related Art

Personal immersion devices are being developed in various forms, such as head mounted display (HMD) devices, face mounted display (FMD) devices, and eye glasses-type display (EGD) devices. The personal immersion devices are classified into virtual reality (VR) devices and augmented reality (AR) devices.

In the personal immersion device, a distance between a user's eyes and a display panel is small. Display devices for the personal immersion device should have high resolution, high brightness, and low-power driving.

To improve a form factor of the personal immersion device, it is desirable to decrease the size of a lens closest to the user's eyes. As the size of the lens decreases, there are differences in color/viewing angle characteristics of light emitted from front and side surfaces of the device, which can impair image quality and distract from the viewing experience.

### SUMMARY OF THE DISCLOSURE

The present specification is directed to achieving the necessity and/or solving the problems that are described above.

The present specification provides a display panel that improves the appearance and/or size of a personal immersion device by decreasing the size of an eyepiece closest to a user's eyes, and a personal immersion device including the same.

The present specification provides a display panel in which light leakage is prevented and luminous efficiency is increased so that high brightness is achieved, a display device including the same, and a personal immersion device including the same.

The objects of the present specification are not limited to the above-described objects, and other objects that are not mentioned will be able to be clearly understood by those skilled in the art from the following description.

A display panel according to the present specification includes a substrate including a first display area and a second display area surrounding the first display area and including a plurality of sub-pixels disposed in the first display area and the second display area, a light emitting layer configured to emit light in each of the plurality of sub-pixels, a color filter layer disposed on the light emitting layer, and a plurality of condensing lenses disposed on the color filter layer. The plurality of condensing lenses are disposed to correspond one-to-one to emission areas of the plurality of sub-pixels disposed in the second display area, and a central axis of the condensing lens is misaligned with a central axis of the emission area corresponding to the condensing lens.

The first display area can include a first side surface and a second side surface that face each other and a third side surface and a fourth side surface that face each other, and the second display area can include a 2-1 display area disposed at the first side surface, a 2-2 display area disposed at the second side surface, a 2-3 display area disposed at the third side surface, and a 2-4 display area disposed at the fourth side surface.

A minimum distance between a central axis based on a central portion of the first display area and the central axis of the condensing lens can be smaller than a minimum distance between the central axis based on the central portion of the first display area and the central axis of the emission area corresponding to the condensing lens.

A first orthogonally projected area in which at least one of the plurality of condensing lenses is orthogonally projected onto a plane including the emission area can include a 1-2 orthogonally projected area overlapping with the emission area and a 1-1 orthogonally projected area that is the rest of the first orthogonally projected area excluding the 1-2 orthogonally projected area, and an area of the 1-2 orthogonally projected area can be greater than an area of the 1-1 orthogonally projected area.

When viewed from a planar direction of the emission area, a central portion of the condensing lens can be shifted to a side at which the first display area is disposed as compared to a central portion of the emission area corresponding to the condensing lens.

The color filter layer can include a plurality of color filters disposed to correspond one-to-one to the plurality of sub-pixels, and a black matrix disposed between the plurality of color filters, and when viewed from a planar direction of the display panel, the plurality of color filters can be shifted to the side at which the first display area is disposed.

A shifted length of the central portion of the condensing lens to the side at which the first display area is disposed in a condensing lens disposed relatively away from the first display area can be greater than that of a condensing lens disposed relatively close to the first display area.

The plurality of sub-pixels can include first to third sub-pixels, the plurality of color filters can include first to third color filters disposed to correspond one-to-one to the first to third sub-pixels, the plurality of condensing lenses can include first to third condensing lenses disposed to correspond one-to-one to the first to third sub-pixels, and central portions of the first to third condensing lenses are formed at positions corresponding one-to-one to central portions of the first to third color filters.

The central portion of the condensing lens can overlap with the central portion of the color filter that corresponds to the sub-pixel including the emission area corresponding to the condensing lens in the planar direction of the emission area.

The condensing lens can include a semi-circular or semi-elliptical cross section, and a refractive index of the condensing lens can be higher than a refractive index of an area outside the condensing lens disposed in a direction in which light travels from the condensing lens.

Light emitted from the first display area can travel straight, and light emitted from the second display area can be refracted by the condensing lens.

The display panel according to the present specification can further include a circuit element disposed between the substrate and the light emitting layer, a first electrode disposed between the circuit element and the light emitting layer, a bank that covers an end of the first electrode, and a second electrode disposed between the light emitting layer and the color filter layer, in which the light emitting layer can include a first stack that is disposed between the first electrode and the second electrode and emits light of a first color, a second stack that is disposed on the first stack and emits light of a second color, and a charge generation layer disposed between the first stack and the second stack.

The plurality of sub-pixels can include first to third sub-pixels, the bank can include a first trench disposed in boundary areas between the first to third sub-pixels, and the first stack and the charge generation layer can be partitioned into a plurality of pieces by the first trench.

The plurality of sub-pixels can include first to third sub-pixels, and the display panel can further include a bank structure disposed on the bank, disposed in boundary areas between the first to third sub-pixels, and provided with side portions in an undercut shape.

The first stack and the charge generation layer can be separated on the side portions of the bank structure.

The display panel according to the present specification can further include a second trench formed in an upper portion of the bank structure.

The light emitting layer can be disposed on the bank structure, and the first stack and the charge generation layer can be separated by the second trench.

A display device according to the present specification includes a display panel on which a plurality of data lines, a plurality of gate lines, and a plurality of sub-pixels electrically connected to the data lines and the gate lines are disposed, and a display driving unit configured to write data to the display panel and drive the display panel, in which the display panel includes a substrate including a first display area and a second display area surrounding the first display area and including a plurality of sub-pixels disposed in the first display area and the second display area, a light emitting layer configured to emit light in each of the plurality of sub-pixels, a color filter layer disposed on the light emitting layer, and a plurality of condensing lenses disposed on the color filter layer, the plurality of condensing lenses are disposed to correspond one-to-one to emission areas of the plurality of sub-pixels disposed in the second display area, and a central axis of the condensing lens is misaligned with a central axis of the emission area corresponding to the condensing lens.

A personal immersion device according to the present specification includes a first display panel on which a left-eye image is displayed, a second display panel on which a right-eye image is displayed, a first drive integrated circuit (IC) configured to convert pixel data of the left-eye image into a data voltage and supply the data voltage to data lines of the first display panel, a first gate driving unit configured to sequentially supply a scan pulse to gate lines of the first display panel, a second drive IC configured to convert pixel data of the right-eye image into a data voltage and supply the data voltage to data lines of the second display panel, a second gate driving unit configured to sequentially supply a scan pulse to gate lines of the second display panel, a first eyepiece disposed on the first display panel, and a second eyepiece disposed on the second display panel, in which each of the first display panel and the second display panel includes a substrate including a first display area and a second display area surrounding the first display area, a light emitting element disposed on the substrate, a color filter layer disposed on the light emitting element, and a plurality of condensing lenses disposed on the color filter layer, the plurality of condensing lenses are disposed to correspond one-to-one to emission areas of the plurality of sub-pixels, a central axis of the condensing lens is misaligned with a central axis of the emission area corresponding to the condensing lens, a size of the first eyepiece is smaller than a size of the first display panel, and a size of the second eyepiece is smaller than a size of the second display panel.

Light emitted from the plurality of condensing lenses of the first display panel can be collected into the first eyepiece, and light emitted from the plurality of condensing lenses of the second display panel can be collected into the second eyepiece.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, which are briefly described below.

FIG. 1 is a view schematically showing a virtual reality device according to an embodiment of the present invention.

FIG. 2 is a block diagram showing a display device according to an embodiment of the present invention.

FIG. 3 is a detailed view showing a display driving unit and a display panel shown in FIG. 2 according to an embodiment of the present invention.

FIG. 4 is a view showing a distance between first and second display panels shown in FIG. 3 according to an embodiment of the present invention.

FIG. 5 is a plan view showing a portion of a display panel according to an embodiment of the present invention.

FIG. 6 is an enlarged partial view showing portion P in FIG. 5 according to an embodiment of the present invention.

FIG. 7 is a cross-sectional view along line H-H′ in FIG. 6 according to an embodiment of the present invention.

FIG. 8 is a schematic view showing a first display area and a second display area according to an embodiment of the present invention.

FIG. 9 is a view showing an area in which the second display area according to an embodiment of the present invention is partitioned.

FIG. 10 is a first modified example of FIG. 9 according to an embodiment of the present invention.

FIG. 11 is a second modified example of FIG. 9 according to an embodiment of the present invention.

FIG. 12 is a third modified example of FIG. 9 according to an embodiment of the present invention.

FIG. 13 is a view showing a portion of a display panel according to another embodiment of the present invention.

FIG. 14 is a schematic view showing a first display area and a second display area according to another embodiment of the present invention.

FIG. 15 is a view showing an area in which the second display area according to another embodiment of the present invention is partitioned.

FIG. 16 is a first modified example of FIG. 15 according to an embodiment of the present invention.

FIG. 17 is a view showing a location of an example cross-sectional portion in the display panel according to one embodiment of the present invention in a plan view.

FIG. 18 is a cross-sectional view along line I-I′ in FIG. 17 according to an embodiment of the present invention.

FIGS. 19A and 19B are longitudinal cross-sectional views showing a condensing lens according to one embodiment of the present invention.

FIG. 20 is a view for describing a traveling direction of light in the first display area and the second display area according to an embodiment of the present invention.

FIG. 21 is a cross-sectional view along line I-I″ in FIG. 17 according to an embodiment of the present invention.

FIG. 22 is a simulation graph showing a brightness relative value of the display panel according to an embodiment of the present invention.

FIG. 23 is a first modified example of the display panel according to an embodiment of the present invention.

FIG. 24 is a second modified example of the display panel according to an embodiment of the present invention.

FIG. 25 is a third modified example of the display panel according to an embodiment of the present invention.

FIGS. 26A to 26L are schematic cross-sectional views showing processes of manufacturing the second and third modified examples of the display panel according to embodiments of the present invention.

FIG. 27 is an exploded perspective view showing a personal immersion device according to an embodiment of the present invention.

### DETAILED DESCRIPTION OF THE EMBODIMENTS

Advantages and features of the invention disclosed the present specification and methods for achieving them will become clear with reference to embodiments described below in detail in conjunction with the accompanying drawings. The present invention is not limited to embodiments disclosed below but can be implemented in various different forms, the embodiments are merely provided to make the disclosure of the present invention complete and fully inform those skilled in the art to which the present invention pertains of the scope of the present invention, and the present invention is only defined by the scope of the appended claims.

In describing the present invention, when it is determined that the detailed description of a related known technology can unnecessarily obscure the gist of the present invention, detailed description thereof will be omitted.

When the terms “comprise,” “can include,” “have,” and “consist of”' described in the present specification are used, other parts can be added unless “only” is used. When a component is expressed in the singular, it can be construed as a plurality of components unless specifically stated otherwise.

When the position relationship and interconnection relationship between two components, such as “on,” “above,” “under,” “next to,” “connected or coupled,” or “crossing or intersecting,” are described, one or more other components can be interposed between the components unless the term “immediately” or “directly” is described.

When the temporal relationship is described using the term “after,” “subsequently,” “then,” “before,” or the like, it may not be consecutive on a time axis unless the term “immediately” or “directly” is used.

Although the term “first,” “second,” or the like can be used to distinguish components, functions or structures of the components are not limited by the ordinal number or component name added to the front of the component.

In the present specification, a planar direction of a display panel can be substantially the same as a planar direction, XY planar direction, X1Y1 planar direction, X1Y2 planar direction, X2Y1 planar direction, or X2Y2 planar direction of an emission area.

The following embodiments can be partially or fully coupled or combined, and various technological interworking and driving are possible. The embodiments can be implemented independently of each other and implemented together in the associated relationship.

Terms (including technical and scientific terms) used in embodiments of the present specification can be construed as meanings that can be generally understood by those skilled in the art to which the present specification pertains unless explicitly specifically defined and described, and the meanings of the commonly used terms, such as terms defined in a dictionary, can be construed in consideration of contextual meanings of related technologies. The term “can” fully encompasses all the meanings and coverages of the term “may.”

Hereinafter, embodiments of the present invention will be described in detail with reference to the accompanying drawings.

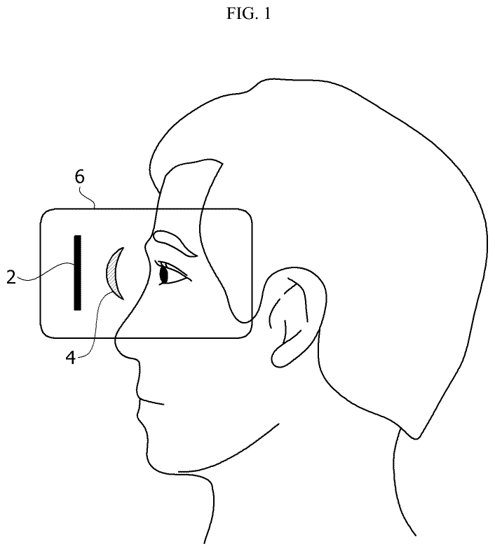

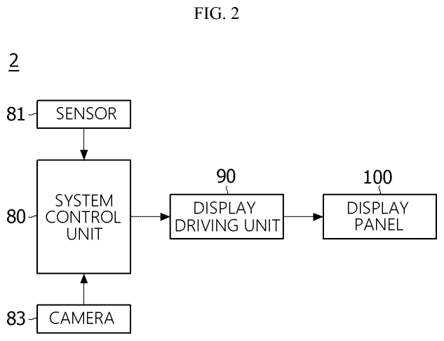

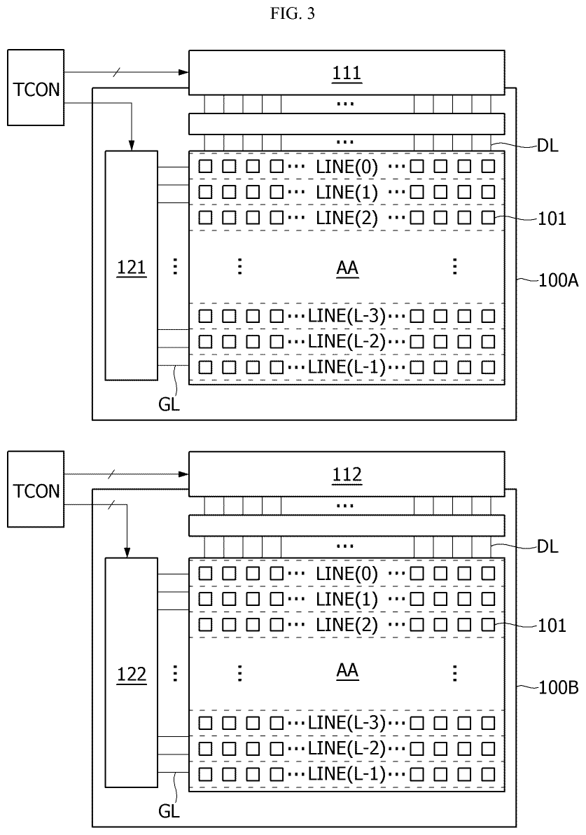

FIG. 1 is a schematic view showing a virtual reality device. FIG. 2 is a block diagram showing a display device according to an embodiment of the present invention. FIG. 3 is a detailed view showing a display driving unit and a display panel shown in FIG. 2 according to embodiments of the present invention.

Referring to FIGS. 1 and 2, a user sees a three-dimensional image displayed on a screen 2 through an eyepiece 4. For example, the eyepiece 4 can be a fisheye lens.

The screen 2 can include a system control unit 80, a display driving unit 90, a display panel 100, and the like.

The system control unit 80 can be connected to a sensor 81, a camera 83, and the like. The system control unit 80 can further include an external device interface connected to a memory or an external video source, a user interface for receiving user commands, a power supply unit for generating power, and the like. The external device interface, the user interface, the power supply unit, and the like can further be included. The external device interface can be implemented as various types of known interface modules, such as a universal serial bus (USB) and a high definition multimedia interface (HDMI).

The sensor 81 can include various sensors, such as a gyro sensor and an acceleration sensor. The sensor 81 can transmit outputs of various sensors to the system control unit 80. The system control unit 80 can receive an output of the sensor 81 and move pixel data of images displayed on a screen in synchronization with the user's movement.

The display driving unit 90 can include a drive IC (SDIC) and a gate driver (GIP). When the display driving unit 90 receives pixel data of input images from the system control unit 80, the display driving unit 90 can write the pixel data to pixels of the display panel 100.

Referring to FIG. 3, the display panel 100 can include a first display panel 100A on which a left-eye image is displayed and a second display panel 100B on which a right-eye image is displayed.

The display panels 100A and 100B can include data lines DL, gate lines GL, and pixels 101. Screens of the display panels 100A and 100B can include a pixel array AA on which images are displayed. The pixel array AA can include pixel lines LINE(0) to LINE(L-1) which are sequentially scanned by a scan pulse shifted in a scanning direction and to which the pixel data is written, where L is a positive integer.

In the display driving unit 90, data drivers 111 and 112 and gate drivers 121 and 122 are separated for each of the display panels 100A and 100B, and a timing controller TCON can be shared with the display driving units 90 of the display panels 100A and 100B. Alternatively, a plurality of timing controllers TCON can be connected one-to-one to the display driving units 90 of the display panels 100A and 100B.

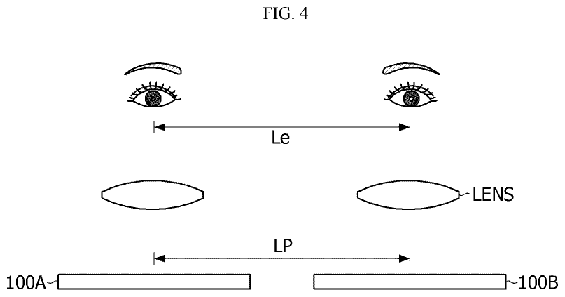

FIG. 4 is a view showing a distance between first and second display panels shown in FIG. 3 according to an embodiment of the present invention.

Referring to FIG. 4, each of the first and second display panels 100A and 100B can be implemented as an organic light emitting diode (hereinafter referred to as “OLED”) display panel that has a fast response time, an excellent color gamut, and a wide viewing angle. In the eye glasses-type display (EGD) device, the display panels 100A and 100B can be implemented as transparent OLED display panels (e.g., for providing an augmented reality view, etc.).

The first and second display panels 100A and 100B can be manufactured separately and disposed to be spaced apart from each other. Although a distance “LP” between the center of the pixel array of the first display panel 100A and the center of the pixel array of the second display panel 100B can be substantially the same as a distance “Le” between the user's eyes, the present invention is not necessarily limited thereto.

When the pixel arrays of the display panels 100A and 100B are separated and the distance between the centers of the pixel arrays matches distances of the left and right eyes of the user, a wide viewing angle can be implemented, and the three-dimensional effect can be greatly improved. The pupil of the user's left eye can match the center of the first pixel array of the first display panel 100A, and the pupil of the user's right eye can match the center of the second pixel array of the second display panel 100B.

In a personal immersion device, an eyepiece LENS can be present between the user's eye and the display panel. When the user views images reproduced on the display panels 100A and 100B through eyepieces LENS, the user can see images that appear 4 to 5 times larger than images in actual screens displayed on the display panels 100A and 100B.

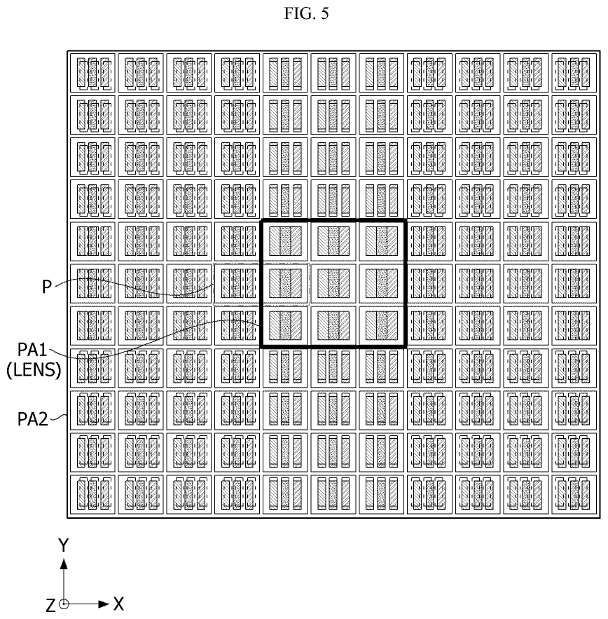

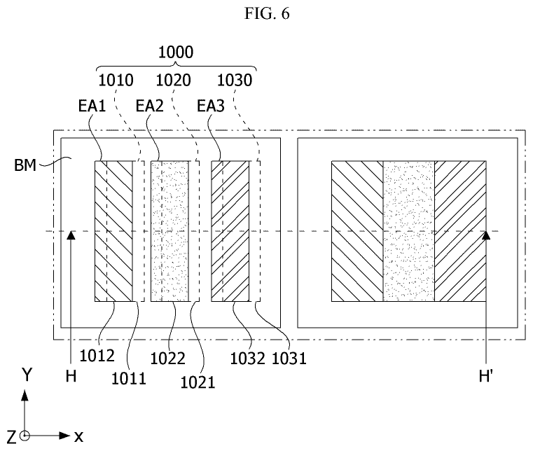

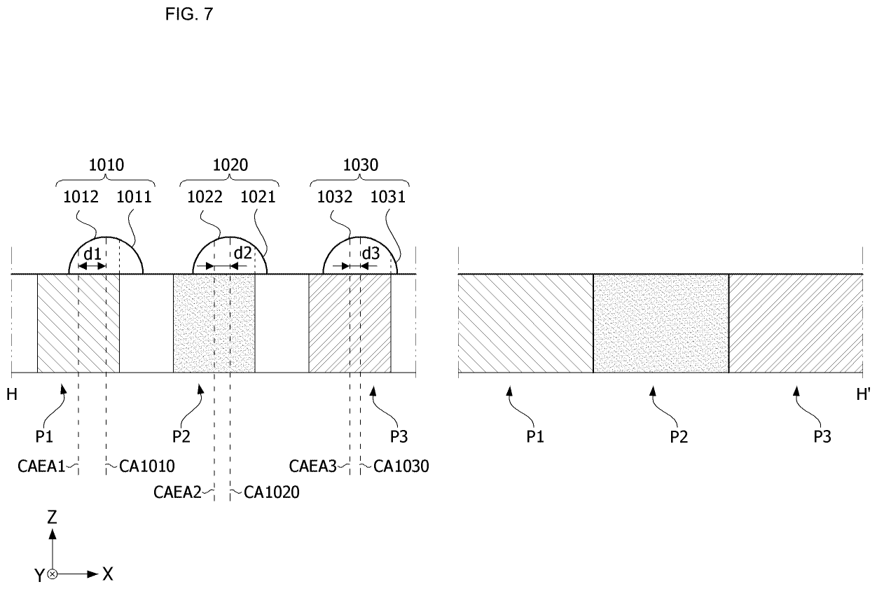

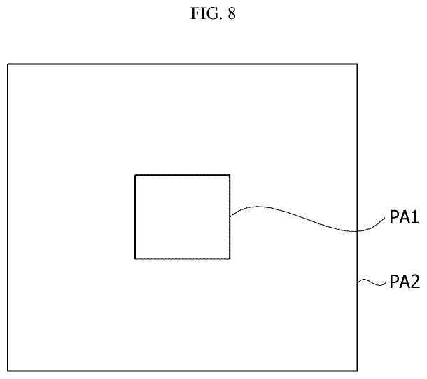

FIG. 5 is a plan view showing a portion of a display panel according to an embodiment of the present invention. FIG. 6 is an enlarged partial view showing portion P in FIG. 5 according to an embodiment of the present invention. FIG. 7 is a cross-sectional view along line H-H′ in FIG. 6 according to an embodiment of the present invention. FIG. 8 is a schematic view showing a first display area and a second display area according to an embodiment of the present invention.

Referring to FIGS. 5 to 8, each of the display panels 100A and 100B according to the embodiment can include a first display area PA1 and a second display area PA2.

The eyepiece LENS can be disposed on or overlapping with the first display area PA1. A condensing lens may not be disposed on the first display area PA1. A central portion of the first display area PA1 can correspond to a center position of the pixel arrays corresponding to the user's eye. The first display area PAI can overlap with an area in which the condensing lens LENS is disposed in a planar direction of the display panel. A shape of the eyepiece LENS that is orthogonally projected in the planar direction of the display panel can be substantially the same as the first display area PA1. For example, a size of the eyepiece LENS can correspond to a size of the first display area PA1.

The size of the eyepiece LENS can be smaller than the size of the display panel 100. As the eyepiece LENS decreases, the sizes of the display device and the personal immersion device can decrease, and the form factor can be improved. It is possible to enhance user convenience and the like by improving the appearance and/or hardware of the display device and the personal immersion device.

The second display area PA2 can surround the first display area PA1. The eyepiece is not disposed in the second display area PA2, and condensing lenses 1010, 1020, and 1030 can be disposed therein.

Each of the first display area PA1 and the second display area PA2 can include a plurality of sub-pixels P1, P2 and P3. The plurality of sub-pixels P1, P2 and P3 can include emission areas EA1, EA2 and EA3, respectively.

The first display area PA1 can further include a black matrix BM surrounding the plurality of sub-pixels P1, P2, and P3. Also, the black matrix BM of the first display area PA1 can be disposed between the plurality of sub-pixels P1, P2 and P3 like that of the second display area PA2.

The second display area PA2 can further include the plurality of condensing lenses 1010, 1020 and 1030 and the black matrix BM surrounding the plurality of sub-pixels P1, P2 and P3. The black matrix BM can also be disposed between the plurality of sub-pixels P1, P2 and P3. Detailed description of the black matrix BM is made below.

The emission areas EA1, EA2, and EA3 can each emit any one of red, green, and blue light and do not overlap with each other. For example, the first emission area EA1 can emit red light, the second emission area EA2 can emit green light, and the third emission area EA3 can emit blue light. Alternatively, the first emission area EA1 can emit green light, the second emission area EA2 can emit red light, and the third emission area EA3 can emit blue light. Alternatively, the first emission area EA1 can emit blue light, the second emission area EA2 can emit green light, and the third emission area EA3 can emit red light. However, the present invention is not limited to the example order discussed above. Also, one of the emission areas can emit other colors of light, such as white light (e.g., a fourth sub-pixel can be provided within a unit pixel).

The plurality of condensing lenses 1010, 1020 and 1030 can include the first condensing lens 1010 disposed on the first emitting area EA1, the second condensing lens 1020 disposed on the second emission area EA2, and the third condensing lens 1030 disposed on the third emission area EA3.

In each of the first, second and third condensing lenses 1010, 1020 and 1030, areas 1011, 1012, 1021, 1022, 1031 and 1032 in which the first, second and third condensing lenses 1010, 1020 and 1030 are orthogonally projected can be defined on a plane including the emission areas EA1, EA2 and EA3. For example, the first orthogonally projected areas 1011 and 1012 in which the first condensing lens 1010 is orthogonally projected can be defined on the plane including the first emission area EA1 from the first condensing lens 1010. The second orthogonally projected areas 1021 and 1022 in which the second condensing lens 1020 is orthogonally projected can be defined on the plane including the second emission area EA2 from the second condensing lens 1020. The third orthogonally projected areas 1031 and 1032 in which the third condensing lens 1030 is orthogonally projected can be defined on the plane including the third emission area EA3 from the third condensing lens 1030. The first to third orthogonally projected areas 1011, 1012, 1021, 1022, 1031 and 1032 can have the same quadrangular shape as the first to third emission areas EA1, EA2, and EA3 or have a circular or elliptical shape. In other words, the first, second and third condensing lenses 1010, 1020 and 1030 can be slight shifted closer towards the first display area PA1 than their corresponding emission areas EA1, EA2 and EA3.

Each of the first to third orthogonally projected areas 1011, 1012, 1021, 1022, 1031 and 1032 can partially overlap with each of the first to third emission areas EA1, EA2 and EA3 in the planar direction of the display panel.

The first orthogonally projected areas 1011 and 1012 can include the 1-2 orthogonally projected area 1012 that overlaps with the first emission area EA1 and the 1-1 orthogonally projected area 1011 that does not overlap with the first emission area EA1. The 1-2 orthogonally projected area 1012 indicates an area only overlapping with the first emission area EA1 and indicates an entire overlapping area. The 1-1 orthogonally projected area 1011 can be the first orthogonally projected area excluding the 1-2 orthogonally projected area 1012. An area of the 1-2 orthogonally projected area 1012 can be greater than an area of the 1-1 orthogonally projected area 1011. For example, a majority of each of the first, second and third condensing lenses 1010, 1020 and 1030 can overlap with than their corresponding emission areas EA1, EA2 and EA3, while some parts of each of the first, second and third condensing lenses 1010, 1020 and 1030 do not overlap with the emission areas EA1, EA2 and EA3 and are slightly shifted towards the first display area PA1.

The second orthogonally projected areas 1021 and 1022 can include the 2-2 orthogonally projected area 1022 that overlaps with the second emission area EA2 and the 2-1 orthogonally projected area 1021 that does not overlap with the second emission area EA2. The 2-2 orthogonally projected area 1022 indicates an area only overlapping with the second emission area EA2 and indicates an entire overlapping area. The 2-1 orthogonally projected area 1021 can be the second orthogonally projected area excluding the 2-2 orthogonally projected area 1022. An area of the 2-2 orthogonally projected area 1022 can be greater than an area of the 2-1 orthogonally projected area 1021.

The third orthogonally projected areas 1031 and 1032 can include the 3-2 orthogonally projected area 1032 that overlaps with the third emission area EA3 and the 3-1 orthogonally projected area 1031 that does not overlap with the third emission area EA3. The 3-2 orthogonally projected area 1032 indicates an area only overlapping with the third emission area EA3 and indicates an entire overlapping area. The 3-1 orthogonally projected area 1031 can be the third orthogonally projected area excluding the 3-2 orthogonally projected area 1032. An area of the 3-2 orthogonally projected area 1032 can be greater than an area of the 3-1 orthogonally projected area 1031. In other words, each condensing lens can include a first portion that overlaps with a corresponding emission area and a second portion that does not overlap with the emission area, and an area of the overlapping portion can be greater than an area of the non-overlapping portion.

When viewed from the planar direction of the display panel, a central portion of the first condensing lens 1010 and a central portion of the first emission area EA1 can be defined. The central portion of the first condensing lens 1010 can be shifted toward the side at which the first display area PA1 is disposed as compared to the central portion of the first emission area EA1. For example, as shown in FIG. 6, the condensing lenses can be slightly shifted towards the right in a directed towards first display area PA1, when compared to the positions of the underlying emission areas.

When viewed from the planar direction of the display panel, a central portion of the second condensing lens 1020 and a central portion of the second emission area EA2 can be defined. The central portion of the second condensing lens 1020 can be shifted toward the side at which the first display area PA1 is disposed as compared to the central portion of the second emission area EA2.

When viewed from the planar direction of the display panel, a central portion of the third condensing lens 1030 and a central portion of the third emission area EA3 can be defined. The central portion of the third condensing lens 1030 can be shifted toward the side at which the first display area PA1 is disposed as compared to the central portion of the third emission area EA3.

In the planar direction of the display panel, the central portions of the condensing lenses 1010, 1020 and 1030 disposed on the second display area PA2 surrounding the first display area PA1 can be disposed to be misaligned with the central portions of the emission areas EA1, EA2, and EA3 such that the central portions of the lenses are closer to the first display area PA1 than the central portions of the corresponding emission areas. In this way, light emitting from the emission areas can be better directed towards the user's eye.

In the planar direction of the display panel, each of the condensing lenses 1010, 1020, and 1030 can be shifted relatively toward the first display area PA1 as compared to the corresponding emission areas EA1, EA2, and EA3.

With reference to FIG. 7, a central axis CA1010 of the first condensing lens can be misaligned with a central axis CAEA1 of the first emission area EA1 corresponding to the first condensing lens. A central axis CA1020 of the second condensing lens can be misaligned with a central axis CAEA2 of the second emission area EA2 corresponding to the second condensing lens. A central axis CA1030 of the third condensing lens can be misaligned with a central axis CAEA3 of the third emission area EA3 corresponding to the third condensing lens.

In a plan view of the display panel, the central axis CA1010 of the first condensing lens may not match the central axis CAEA1 of the first emission area EA1 corresponding to the first condensing lens. In the plan view of the display panel, the central axis CA1020 of the second condensing lens may not match the central axis CAEA2 of the second emission area EA2 corresponding to the second condensing lens. In the plan view of the display panel, the central axis CA1030 of the third condensing lens may not match the central axis CAEA3 of the third emission area EA3 corresponding to the third condensing lens.

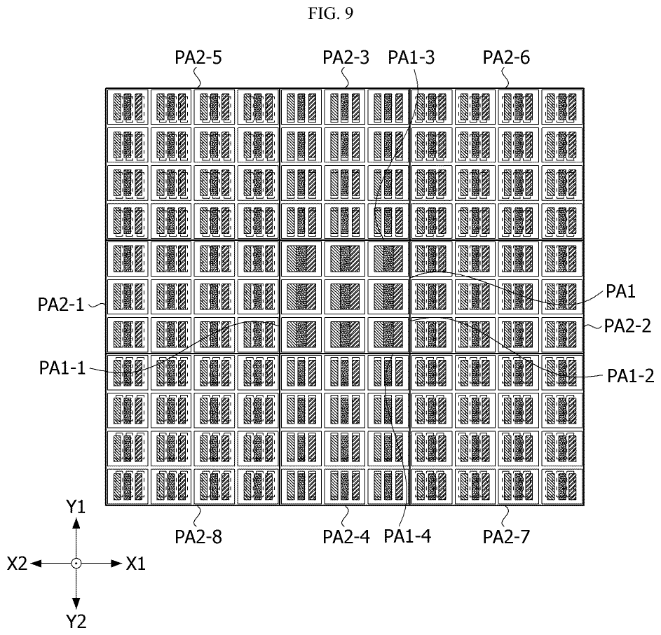

FIG. 9 is a view showing an area in which the second display area according to an embodiment of the present invention is partitioned.

Referring to FIG. 9, the first display area PA1 can include a first side surface PA1-1 (e.g., left side) and a second side surface PA1-2 (e.g., right side) that face each other and a third side surface PA1-3 (e.g., upper side) and a fourth side surface PA1-4 (e.g., lower side) that face each other. The second display area PA2 can include a 2-1 display area PA2-1 (e.g., left middle area) disposed at a first side surface PA1-1 side (e.g., left side), a 2-2 display area PA2-2 (e.g., right middle area) disposed at a second side surface PA1-2 side (e.g., right side), a 2-3 display area PA2-3 (e.g., upper center area) disposed at a third side surface PA1-3 side (e.g., upper side), and a 2-4 display area PA2-4 (e.g., lower center area) disposed at a fourth side surface PA1-4 side (e.g., lower side).

The second display area PA2 can further include a 2-5 display area PA2-5 (e.g., upper left corner area) disposed between the 2-1 display area PA2-1 (e.g., left middle area) and the 2-3 display area PA2-3 (e.g., upper center area), a 2-6 display area PA2-6 (e.g., upper right corner area) disposed between the 2-2 display area PA2-2 (e.g., right middle area) and the 2-3 display area PA2-3 (e.g., upper center area), a 2-7 display area PA2-7 (e.g., lower right corner area) disposed between the 2-2 display area PA2-2 (e.g., right middle area) and the 2-4 display area PA2-4 (e.g., lower center area), and a 2-8 display area PA2-8 (e.g., lower left corner area) disposed between the 2-1 display area PA2-1 (e.g., left middle area) and the 2-4 display area PA2-4 (lower center area).

The condensing lenses 1010, 1020 and 1030 disposed on the 2-1 display area PA2-1 (e.g., left middle area) can be misaligned in an X1-axis direction in which the first display area PA1 is disposed as compared to the corresponding emission areas EA1, EA2, and EA3. For example, condensing lenses 1010, 1020 and 1030 disposed on the 2-1 display area PA2-1 (e.g., left middle area) can be slightly shifted towards the right in a direction towards the first display area PA1.

The condensing lenses 1010, 1020, and 1030 disposed on the 2-2 display area PA2-2 (e.g., right middle area) can be misaligned in an X2-axis direction in which the first display area PA1 is disposed as compared to the corresponding emission areas EA1, EA2, and EA3. For example, condensing lenses 1010, 1020 and 1030 disposed on the 2-2 display area PA2-2 (e.g., right middle area) can be slightly shifted towards the left in a direction towards the first display area PA1.

The condensing lenses 1010, 1020, and 1030 disposed on the 2-3 display area PA2-3 (e.g., upper center area) can be misaligned in a Y2-axis direction in which the first display area PA1 is disposed as compared to the corresponding emission areas EA1, EA2, and EA3. For example, condensing lenses 1010, 1020 and 1030 disposed on the 2-3 display area PA2-3 (e.g., upper center area) can be slightly shifted downward in a direction towards the first display area PA1.

The condensing lenses 1010, 1020, and 1030 disposed on the 2-4 display area PA2-4 (e.g., lower center area) can be misaligned in a Y1-axis direction in which the first display area PA1 is disposed as compared to the corresponding emission areas EA1, EA2, and EA3. For example, condensing lenses 1010, 1020 and 1030 disposed on the 2-4 display area PA2-4 (e.g., lower center area) can be slightly shifted upward in a direction towards the first display area PA1.

The condensing lenses 1010, 1020, and 1030 disposed on the 2-5 display area PA2-5 (e.g., upper left corner area) can be misaligned in a diagonal direction of the X1-axis and Y2-axis directions in which the first display area PA1 is disposed as compared to the corresponding emission areas EA1, EA2, and EA3.

The condensing lenses 1010, 1020, and 1030 disposed on the 2-6 display area PA2-6 (e.g., upper right corner area) can be misaligned in a diagonal direction of the X2-axis and Y2-axis directions in which the first display area PA1 is disposed as compared to the corresponding emission areas EA1, EA2, and EA3.

The condensing lenses 1010, 1020, and 1030 disposed on the 2-7 display area PA2-7 (e.g., lower right corner area) can be misaligned in a diagonal direction of the X2-axis and Y1-axis direction in which the first display area PA1 is disposed as compared to the corresponding emission areas EA1, EA2, and EA3.

The condensing lenses 1010, 1020, and 1030 disposed on the 2-8 display area PA2-8 (e.g., lower left corner area) can be misaligned in a diagonal direction of the X1-axis and Y1-axis directions in which the first display area PA1 is disposed as compared to the corresponding emission areas EA1, EA2, and EA3.

For example, the condensing lenses in each of the four corner areas can be slightly shifted in a diagonal direction towards the first display area PA1. In this way, emitted light be can better directed towards a user's eye.

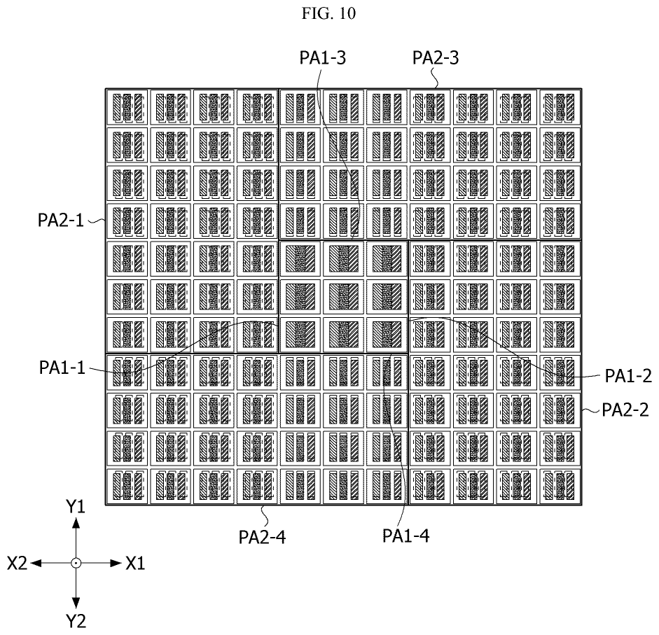

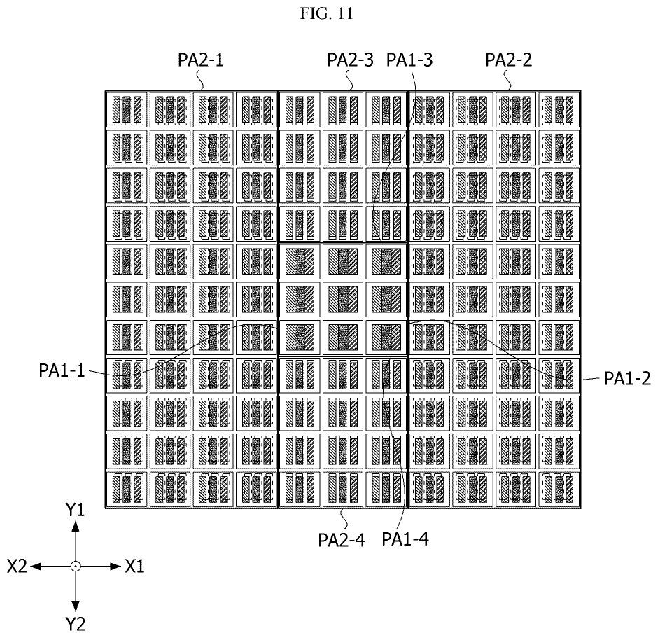

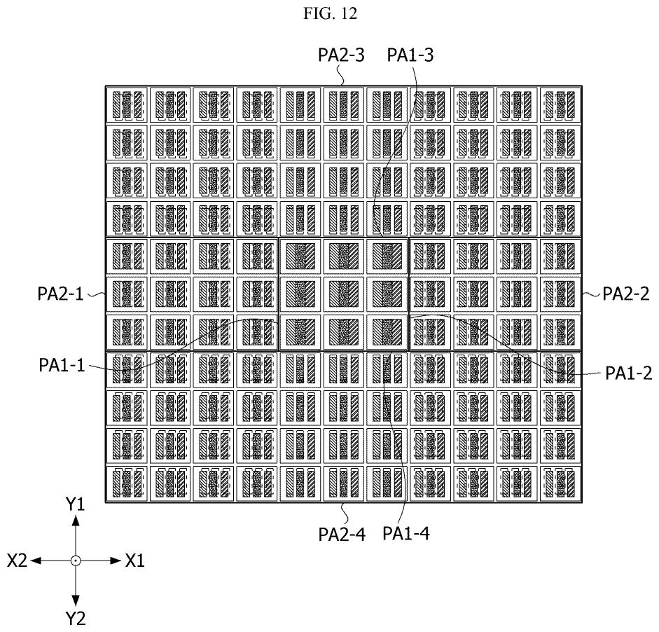

FIGS. 10 to 12 are various modified examples of an area in which the second display area according to embodiments of the present invention is partitioned. FIG. 10 is a first modified example of FIG. 9 according to an embodiment of the present invention. FIG. 11 is a second modified example of FIG. 9 according to an embodiment of the present invention. FIG. 12 is a third modified example of FIG. 9 according to an embodiment of the present invention.

Referring to FIGS. 10, 11 and 12, the first display area PA1 can include the first side surface PA1-1 and the second side surface PA1-2 that face each other, and the third side surface PA1-3 and the fourth side surface PA1-4 that face each other, and the second display area PA2 can include the 2-1 display area PA2-1 disposed at the first side surface PA1-1 side, the 2-2 display area PA2-2 disposed at the second side surface PA1-2 side, the 2-3 display area PA2-3 disposed at the third side surface PA1-3 side, and the 2-4 display area PA2-4 disposed at the fourth side surface PA1-4 side.

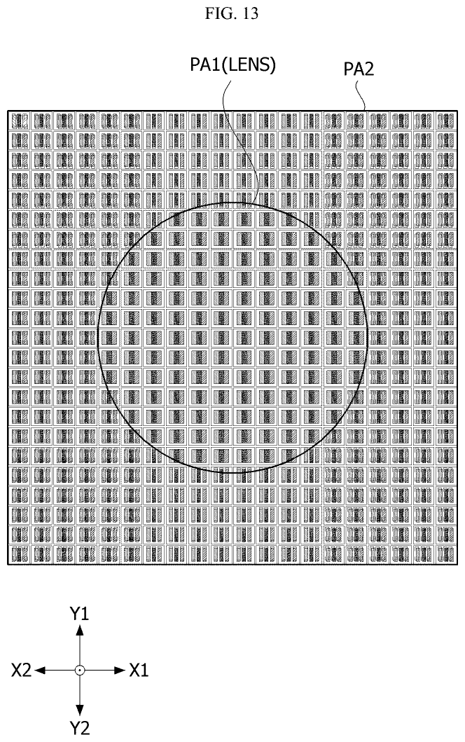

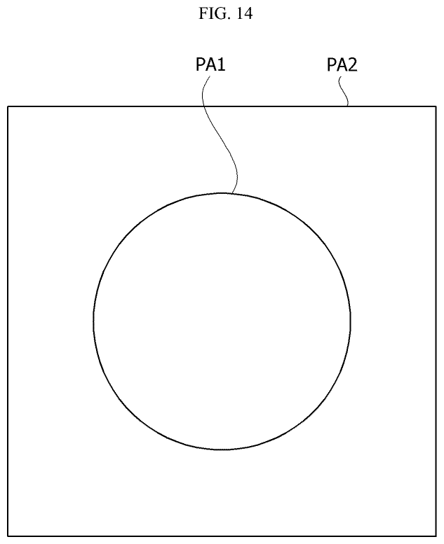

FIG. 13 is a view showing a portion of a display panel according to another embodiment of the present invention. FIG. 14 is a schematic view showing a first display area and a second display area according to another embodiment of the present invention.

Referring to FIGS. 13 and 14, each of the display panels 100A and 100B according to the embodiment can include the first display area PA1 and the second display area PA2. In the display panel according to the embodiment, the shape of the first display area is a circle or an ellipse, which differs from that of the first display area PA1 according to FIGS. 5 and 6. The first display area PA1 can be substantially the same as an area in which the eyepiece LENS is disposed. A shape of the eyepiece LENS that is orthogonally projected in the planar direction of the display panel can be substantially the same as the first display area PA1. Therefore, the shape of the eyepiece LENS that is orthogonally projected in the planar direction of the display panel can be a circle or an ellipse.

In the drawings, a shape of an outer area of the pixel disposed in the first display area PA1 may not be shown as a circle or ellipse due to a low resolution (due to a small number of pixels), but as the resolution increases (when the number of pixels is large), the outer area can be close to or substantially equal to a circular or elliptical shape.

Except for the shape of the second display area PA2 shown, the condensing lenses disposed in the second display area PA2, a directivity in which the condensing lens is disposed, and the like is the same as the above description of the same reference numerals shown in the drawings. For example, the condensing lenses are slightly shifted in a direction towards the first display area PA1.

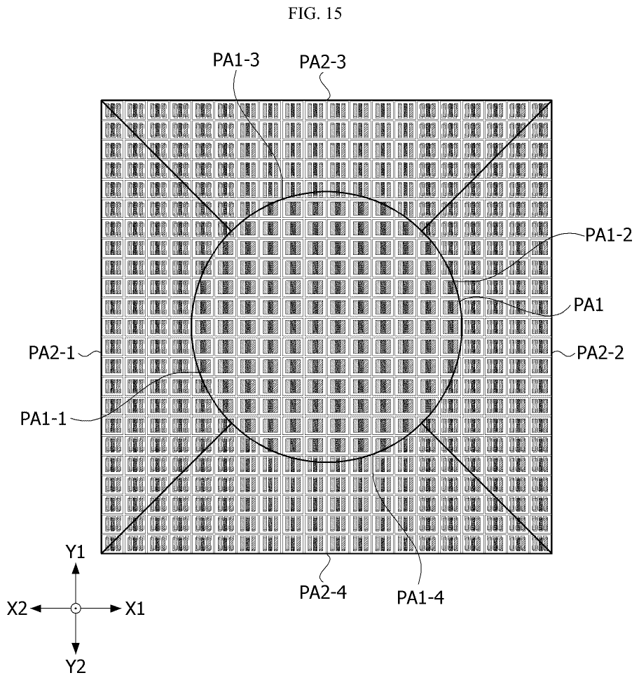

FIG. 15 is a view showing an area in which the second display area according to another embodiment of the present invention is partitioned.

Referring to FIG. 15, the first display area PA1 can include the first side surface PA1-1 (e.g., left arc portion) and the second side surface PA1-2 (e.g., right arc portion) that face each other, and the third side surface PA1-3 (e.g., upper arc portion) and the fourth side surface PA1-4 (e.g., lower arc portion) that face each other, and the second display area PA2 can include the 2-1 display area PA2-1 (e.g., left triangular shaped region) disposed at the first side surface PA1-1 side, the 2-2 display area PA2-2 (e.g., left triangular shaped region) disposed at the second side surface PA1-2 side, the 2-3 display area PA2-3 (e.g., upper triangular shaped region) disposed at the third side surface PA1-3 side, and the 2-4 display area PA2-4 (e.g., lower triangular shaped region) disposed at the fourth side surface PA1-4 side. For example, the 2-1 display area PA2-1, the 2-2 display area PA2-2, 2-3 display area PA2-3 and 2-4 display area PA2-4 can each have a triangular shape with a notched or arced corner area (e.g., cutout portion) due to the first display area PA1 which can have a circle shape, but embodiments are not limited thereto.

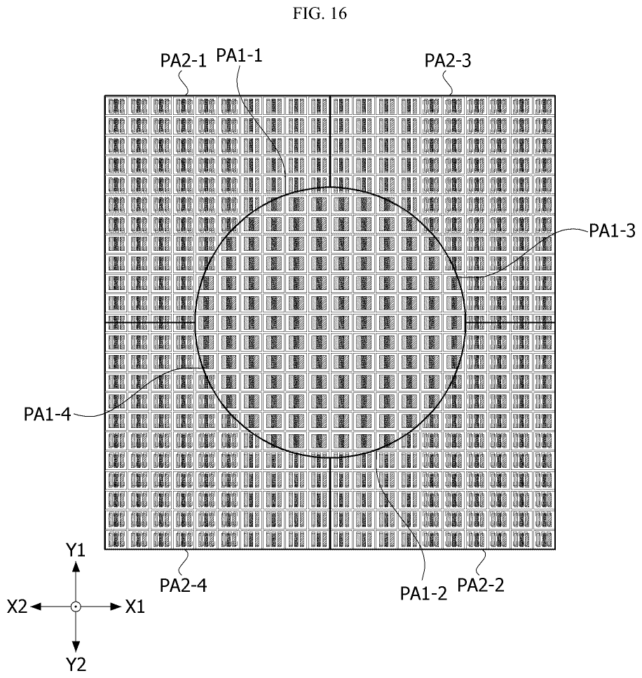

FIG. 16 is a first modified example of FIG. 15. The same components are denoted by the same reference numerals, and descriptions thereof are omitted.

Referring to FIG. 16, the first side surface PA1-1 and the second side surface PA1-2 that face each other may not be parallel to an X-axis and/or a Y-axis. The areas partitioned from the second display area PA2 are not uniform as described above and are not limited as long as the second display area PA2 can partition the directivities in which the condensing lenses 1010, 1020, and 1030 are disposed. For example, the 2-1 display area PA2-1, the 2-2 display area PA2-2, 2-3 display area PA2-3 and 2-4 display area PA2-4 can each have a square shape with a notched or arced corner area (e.g., cutout portion) due to the first display area PA1 which can have a circle shape, but embodiments are not limited thereto. The 2-1 display area PA2-1, the 2-2 display area PA2-2, 2-3 display area PA2-3 and 2-4 display area PA2-4 can be divided into four quadrants disposed around the first display area PA1 which can have a circle shape, but embodiments are not limited thereto.

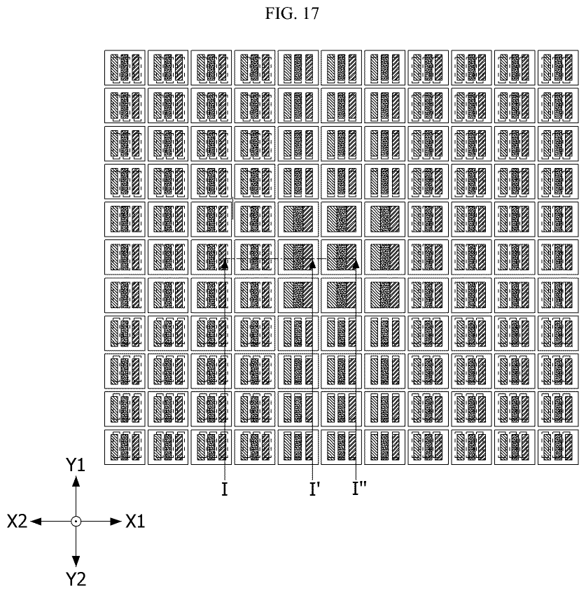

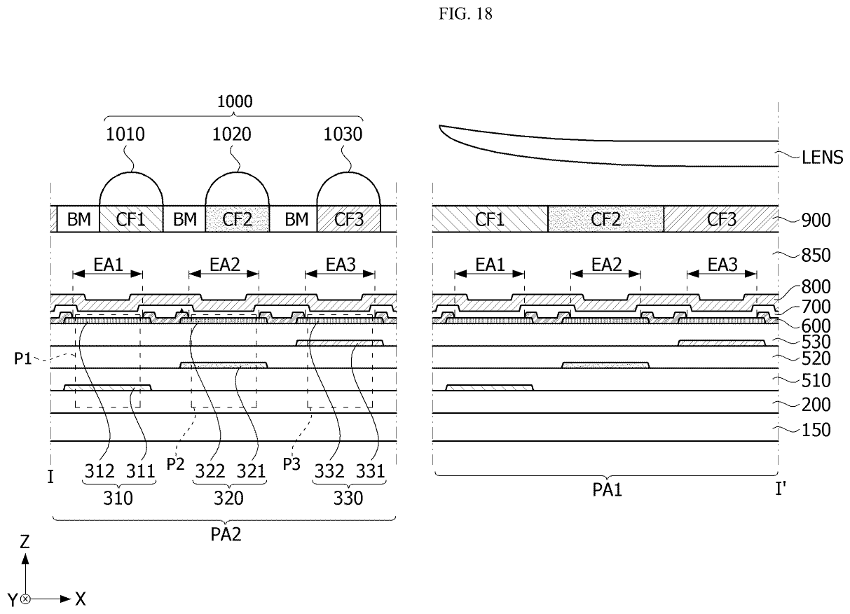

Hereinafter, various embodiments of the present invention will be described through a cross-sectional structure. FIG. 17 is a view showing a location of an example cross-sectional portion in the display panel according to one embodiment of the present invention in a plan view. FIG. 18 is a cross-sectional view along line I-I′ in FIG. 17.

Referring to FIGS. 17 and 18, the first display area PA1 can include a substrate 150, a circuit element layer 200, first electrodes 310, 320 and 330, insulating layers 510, 520 and 530, a bank 600, a light emitting layer 700, a second electrode 800, an encapsulation layer 850 and a color filter layer 900.

A plurality of sub-pixels P1, P2 and P3 can be formed on the substrate 150. Each of the plurality of sub-pixels P1, P2 and P3 can be provided with emission areas EA1, EA2 and EA3. Specifically, the first emission area EA1 can be provided in the first sub-pixel P1, the second emission area EA2 can be in the second sub-pixel P2, and the third emission area EA3 can be provided in the third sub-pixel P3.

The plurality of emission areas EA1, EA2 and EA3 can be defined by the bank 600. Exposed areas not covered by the bank 600 can become the plurality of emission areas EA1, EA2 and EA3.

The first electrodes 310, 320 and 330 can be patterned for each sub-pixel P1, P2 and P3. One first electrode 310 can be formed in the first sub-pixel P1, another first electrode 320 can be formed in the second sub-pixel P2, and still another first electrode 330 can be formed in the third sub-pixel P3. The first electrodes 310, 320, and 330 can serve as an anode (or a positive electrode).

The first electrode 310 of the first sub-pixel P1 can extend across the first emission area EA1, and an exposed portion of the first electrode 310 that is not covered by the bank 600 can become the first emission area EA1.

The second electrode 320 of the second sub-pixel P2 can extend across the second emission area EA2, and an exposed portion of the second electrode 320 that is not covered by the bank 600 can become the second emission area EA2.

The third electrode 330 of the third sub-pixel P3 can extend across the third emission area EA3, and an exposed portion of the third electrode 330 that is not covered by the bank 600 can become the third emission area EA3.

The substrate 150 can be made of a glass or plastic, but is not necessarily limited thereto, and can be made of a semiconductor material, such as a silicon wafer.

The substrate 150 can be made of a transparent material or an opaque material. The first sub-pixel P1, the second sub-pixel P2, and the third sub-pixel P3 can be provided on the substrate 150.

Although the first sub-pixel P1 can emit red light, the second sub-pixel P2 can emit green light, and the third sub-pixel P3 can emit blue light, the present invention is not necessarily limited thereto. For example, the arrangement order of the sub-pixels P1, P2, and P3 can be changed in any of various ways.

The display device can operate in a top emission manner in which the emitted light is emitted upward (e.g., a Z direction), and as a material of the substrate 150, an opaque material as well as a transparent material can be used. However, the present invention is not limited thereto, and the display device can operate in a bottom emission manner, and the configuration of the present invention accordingly can be appropriately modified depending on the developer.

The circuit element layer 200 can be formed on the substrate 150. The circuit element layer 200 can be provided with circuit elements including various signal lines, thin film transistors, capacitors, and the like for each of the sub-pixels P1, P2, and P3. The signal lines can include gate lines, data lines, power lines, and reference lines. The thin film transistors can include a switching thin film transistor, a driving thin film transistor, and a sensing thin film transistor.

The switching thin film transistor can be switched according to a gate signal supplied to the gate line to supply a data voltage supplied from the data line to the driving thin film transistor.

The driving thin film transistor can be switched according to the data voltage supplied from the switching thin film transistor to generate a data current from the power supplied from the power line and supply the data current to the first electrodes 310, 320, and 330.

The sensing thin film transistor can serve to sense a threshold voltage deviation of the driving thin film transistors, which causes the degradation of image quality. Specifically, the current of the driving thin film transistor can be supplied to the reference line in response to a sensing control signal supplied from the gate line or a separate sensing line.

The capacitor can serve to maintain the data voltage supplied to the driving thin film transistor for one frame. The capacitor can be connected to a gate electrode and source electrode of the driving thin film transistor.

The first electrodes 310, 320, and 330 can be patterned in the sub-pixels P1, P2, and P3, respectively, on the circuit element layer 200. One first electrode 310 can be formed in the first sub-pixel P1, another first electrode 320 can be formed in the second sub-pixel P2, and still another first electrode 330 can be formed in the third sub-pixel P3.

The first electrodes 310, 320, and 330 can be connected to a driving thin film transistor 250 provided on the circuit element layer 200. Specifically, the first electrodes 310, 320, and 330 can be connected to a source electrode of the driving thin film transistor 250.

The first electrode 310 provided in the first sub-pixel P1 can include a first lower electrode 311 and a first upper electrode 312.

The first lower electrode 311 can be connected to the driving thin film transistor of the circuit element layer 200 in an area including the first sub-pixel P1. As one embodiment, the first lower electrode 311 can be connected to the driving thin film transistor through a contact hole.

In the first sub-pixel P1, the first lower electrode 311 can be directly connected to the driving thin film transistor provided on the circuit element layer 200, and the first upper electrode 312 can be connected to the first lower electrode 311. Specifically, the first upper electrode 312 can be connected to the first lower electrode 311 through a contact electrode.

In the first emission area EA1 of the first sub-pixel P1, a first insulating layer 510, a second insulating layer 520, and a third insulating layer 530 can be disposed between the first lower electrode 311 and the first upper electrode 312.

The first electrode 320 provided in the second sub-pixel P2 can include a second lower electrode 321 and a second upper electrode 322.

The second lower electrode 321 can be connected to another driving thin film transistor of the circuit element layer 200 in an area including the second sub-pixel P2. The second lower electrode 321 can be connected to the driving thin film transistor through a contact hole.

In the second sub-pixel P2, the second lower electrode 321 can be directly connected to the driving thin film transistor provided on the circuit element layer 200, and the second upper electrode 322 can be connected to the second lower electrode 321. Specifically, the second upper electrode 322 can be connected to the second lower electrode 321 through a contact electrode.

In the second emission area EA2 of the second sub-pixel P2, a second insulating layer 520 and a third insulating layer 530 can be disposed between the second lower electrode 321 and the second upper electrode 322.

The first electrode 330 provided in the third sub-pixel P3 can include a third lower electrode 331 and a third upper electrode 332.

The third lower electrode 331 can be connected to another driving thin film transistor of the circuit element layer 200 in an area including the third sub-pixel P3. As another embodiment, the third lower electrode 331 can be connected to the driving thin film transistor through a contact hole.

In the third sub-pixel P3, the third lower electrode 331 can be directly connected to the driving thin film transistor provided on the circuit element layer 200, and the third upper electrode 332 can be connected to the third lower electrode 331. Specifically, the third upper electrode 332 can be connected to the third lower electrode 331 through a contact electrode.

In the third emission area EA3 of the third sub-pixel P3, a third insulating layer 530 can be disposed between the third lower electrode 331 and the third upper electrode 332.

A distance between the first lower electrode 311 and the first upper electrode 312 in the first sub-pixel P1, a distance between the second lower electrode 321 and the second upper electrode 322 in the second sub-pixel P2, and a distance between the third lower electrode 331 and the third upper electrode 332 in the third sub-pixel P3 are all different, and thus it is possible to achieve the micro-cavity effect. Detailed description thereof will be made below.

The first insulating layer 510 can be disposed on the circuit element layer 200. The first insulating layer 510 can be formed entirely on the areas of the plurality of sub-pixels P1, P2 and P3, and the first insulating layer 510 formed on the first sub-pixel P1, the first insulating layer 510 formed on the second sub-pixel P2, and the first insulating layer 510 formed on the third sub-pixel P3 can be connected.

The second insulating layer 520 can be disposed on the first insulating layer 510. The second insulating layer 520 can be formed entirely on the areas of the plurality of sub-pixels P1, P2 and P3, and the second insulating layer 520 formed on the first sub-pixel P1, the second insulating layer 520 formed on the second sub-pixel P2, and the second insulating layer 520 formed on the third sub-pixel P3 can be connected.

The third insulating layer 530 can be disposed on the second insulating layer 520. The third insulating layer 530 can be formed entirely on the area of the plurality of sub-pixels P1, P2 and P3, and the third insulating layer 530 formed on the first sub-pixel P1, the third insulating layer 530 formed on the second sub-pixel P2, and the third insulating layer 530 formed on the third sub-pixel P3 can be connected.

The display device according to the embodiment can operate in a top emission manner. To this end, the first electrodes 310, 320 and 330 can be formed to allow the light emitted from the light emitting layer 700 to be reflected toward a front surface of the display device (e.g., in the Z direction). To this end, the first to third lower electrodes 311, 321 and 331 positioned at rear surface sides (e.g., lower sides) of the first electrodes 310, 320 and 330 having a double-layer structure are reflective electrodes, and the first to third upper electrodes 312, 322, and 332 positioned on front surface sides (e.g., upper sides) of the first electrodes 310, 320, and 330 can be formed as transparent electrodes or translucent electrodes. In this situation, the first to third upper electrodes 312, 322 and 332 can serve as anodes (or positive electrodes) of the first to third sub-pixels P1, P2 and P3.

The reflective electrode can be an electrode that reflects incident light, the transparent electrode can be an electrode that transmits incident light, and the translucent electrode can be an electrode that transmits some of the incident light and reflects the rest. In terms of transparency, the transparency can be excellent in the order of the reflective electrode, the translucent electrode, and the transparent electrode. In terms of reflectivity, the reflectivity can be excellent in the order of the transparent electrode, the translucent electrode, and the reflective electrode.

The first upper electrode 312 of the first sub-pixel P1, the second upper electrode 322 of the second sub-pixel P2, and the third upper electrode 332 of the third sub-pixel P3 can be patterned using the same material through the same process.

When the first to third lower electrodes 311, 321 and 331 are formed as the reflective electrodes and the first to third upper electrodes 312, 322 and 332 are formed as the transparent electrodes, some of the light emitted from the light emitting layer 700 can transmit the first to third upper electrodes 312, 322 and 332 after reflected from the first to third lower electrodes 311, 321 and 331, and travel upward.

When the first to third lower electrodes 311, 321 and 331 are formed as the reflective electrodes and the first to third upper electrodes 312, 322 and 332 are formed as the translucent electrodes, some of the light emitted from the light emitting layer 700 can transmit the first to third upper electrodes 312, 322 and 332 and travel upward.

Another part of the light emitted from the light emitting layer 700 can be reflected from the first to third upper electrodes 312, 322 and 332, re-reflected from the first to third lower electrodes 311, 321 and 331, and as a result, can travel upward.

Specifically, another part of the light reflected from the first to third upper electrodes 312, 322 and 332 can be reflected from the first to third lower electrodes 311, 321 and 331. In this situation, some of the light reflected from the first to third lower electrodes 311, 321 and 331 can transmit the first to third upper electrodes 312, 322 and 332 and travel upward, and another part of the light reflected from the first to third lower electrodes 311, 321 and 331 can be reflected from the first to third upper electrodes 312, 322 and 332 and travel downward. This can be re-reflected from the first to third lower electrodes 311, 321 and 331, and the above-described processes can be repeated.

As described above, light can be amplified as it is repeatedly reflected back and forth between the first to third lower electrodes 311, 321 and 331 and the first to third upper electrodes 312, 322 and 332, thereby increasing the light efficiency of the display device according to the embodiment.

When distances between the first to third lower electrodes 311, 321 and 331 and the first to third upper electrodes 312, 322 and 332 are integer multiple of a half wavelength (λ/2) of the light emitted from each of the sub-pixels P1, P2 and P3, constructive interference can occur, thereby further amplifying the light. Therefore, when the above-described reflection and re-reflection process is repeated, the degree to which light is amplified can continuously increase, thereby increasing the external extraction efficiency of light. Such a characteristic is called the micro-cavity (resonance) effect.

A first distance between the first lower electrode 311 and the first upper electrode 312 in the first sub-pixel P1, a second distance between the second lower electrode 321 and the second upper electrode 322 in the second sub-pixel P2, and a third distance between the third lower electrode 331 and the third upper electrode 332 in the third sub-pixel P3 can all be configured differently. Therefore, the micro-cavity effect can be achieved in each of the sub-pixels P1, P2 and P3.

For example, although the first distance in the first sub-pixel P1 that emits red light in a long wavelength band can be set to be the longest distance, and the third distance in the third sub-pixel P3 that emits blue light in a short wavelength band can be set to a shortest distance, in FIG. 18, the present invention is not necessarily limited thereto.

In addition, distances between the first to third upper electrodes 312, 322 and 332 and the second electrode 800 in each of the plurality of sub-pixels P1, P2 and P3 can all be the same, and the first to third upper electrodes 312, 322 and 332 can be formed at the same height on the third insulating layer 530. Therefore, since a lower surface of the light emitting layer 700 formed on the first to third upper electrodes 312, 322 and 332 has an overall uniform height, it is possible to improve the profile of the light emitting layer 700 compared to a situation in which the first to third upper electrodes 312, 322 and 332 are formed at different heights. Even in various embodiments below, although the distances between the first to third upper electrodes 312, 322 and 332 and the second electrode 800 in each of the plurality of sub-pixels P1, P2 and P3 are all formed identically, and the first to third upper electrodes 312, 322 and 332 can be formed at the same height on the third insulating layer 530, the present invention is not necessarily limited thereto.

The bank 600 can be formed to cover ends of the first to third upper electrodes 312, 322 and 332 of the first electrodes 310, 320 and 330 on the third insulating layer 530. Therefore, it is possible to solve a problem of the degradation of luminous efficiency due to a current concentrated on the ends of the first to third upper electrodes 312, 322 and 332.

The bank 600 can be formed in a matrix structure at the boundaries between the plurality of sub-pixels P1, P2 and P3 and can define the emission areas EA1, EA2 and EA3, respectively, in the plurality of sub-pixels P1, P2 and P3. The exposed areas of the first to third upper electrodes 312, 322 and 332, on which the bank 600 is not formed, in each of the sub-pixels P1, P2 and P3 can become the emission areas EA1, EA2 and EA3.

A portion of the bank 600 can be formed to overlap with each of the plurality of first electrodes 310, 320 and 330 extending across the plurality of emission areas EA1, EA2 and EA3 in the planar direction of the display panel.

The bank 600 can be formed of a relatively thin inorganic insulating film, but can be formed of a relatively thick organic insulating film.

The light emitting layer 700 can be formed on the first to third upper electrodes 312, 322 and 332 of the first electrodes 310, 320 and 330. The light emitting layer 700 can also be formed on the bank 600. The light emitting layer 700 can also be formed in each of the sub-pixels P1, P2 and P3 and in boundary areas therebetween.

The boundary areas between the sub-pixels P1, P2 and P3 are not only present in the X-axis direction as shown in FIG. 18, but also present in the Y-axis direction as shown in the plan view of FIG. 7.

The light emitting layer 700 can be formed to emit white (W) light. To this end, the light emitting layer 700 can include a plurality of stacks that emit light of different colors. For example, the light emitting layer 700 can include a first stack that emits blue light, a second stack that emits yellow-green light, and a charge generation layer CGL provided between the first stack and the second stack. As another example, the light emitting layer 700 can include the first stack that emits blue light, the second stack that emits green light, the third stack that emits red light, a first charge generation layer provided between the first stack and the second stack, and a second charge generation layer provided between the second stack and the third stack.

Each of the stacks can include a hole injection layer (HIL), a hole transport layer (HTL), an emission layer (EML), an electron transport layer (ETL), an electron transport layer (ETL), and an electron injection layer (EIL). The configuration of the light emitting layer 700 can be modified into various forms known in the art to which the present invention pertains.

The second electrode 800 can be formed on the light emitting layer 700. The second electrode 800 can serve as a cathode (or a negative electrode) of the display device. Like the light emitting layer 700, the second electrode 800 can be formed in each of the sub-pixels P1, P2 and P3 and the boundary areas therebetween. The second electrode 800 can be formed on the bank 600.

The display device can be driven in a top emission manner. To transmit light emitted from the light emitting layer 700 toward the front surface (e.g., an upper portion) of the display device, the second electrode 800 can be made a transparent conductive material.

Since the second electrode 800 can be formed as a translucent electrode, it is possible to achieve the micro-cavity effect for each of the sub-pixels P1, P2 and P3. When the second electrode 800 is a translucent electrode, the light can be repeated reflected back and forth between the second electrode 800 and the first to third lower electrodes 311, 321 and 331 of the first electrodes 310, 320 and 330, thereby achieving the micro-cavity effect. Alternatively, the light can be repeated reflected back and forth between the second electrode 800 and the first to third upper electrodes 312, 322 and 332 of the first electrodes 310, 320 and 330, thereby achieving the micro-cavity effect.

The encapsulation layer 850 can be formed on the second electrode 800 to prevent external moisture from permeating into the light emitting layer 700. Although the encapsulation layer 850 can be made of an inorganic insulating material or formed in a structure in which an inorganic insulating material and an organic insulating material are alternately stacked, the present invention is not necessarily limited thereto.

The color filter layer 900 can be formed on the encapsulation layer 850. The color filter layer 900 can be formed to substantially face the emission areas EA1, EA2, and EA3 in the individual sub-pixels P1, P2 and P3. The color filter layer 900 can include a first color filter CF1, a second color filter CF2, and a third color filter CF3.

Each of the first color filter CF1, the second color filter CF2, and the third color filter CF3 can be any one selected from the group including a red color filter, a green color filter, and a blue color filter. For example, although the first color filter CF1 provided in the first sub-pixel P1 can include a red color filter, the second color filter CF2 provided in the second sub-pixel P2 can include a green color filter, and the third color filter CF3 provided in the third sub-pixel P3 can include a blue color filter, the present invention is not necessarily limited to the above order or colors (e.g., a white sub-pixel can be included or other color). The first color filter CF1, the second color filter CF2, and the third color filter CF3 can be selected from the group including the red, green, and blue color filters not to overlap with each other.

The color filter layer 900 can include the first color filter CF1, the second color filter CF2, the third color filter CF3, and a black matrix BM disposed at the boundaries therebetween. The black matrix BM can serve to prevent light from leaking, as will be described below.

The second display area PA2 can include the substrate 150, the circuit element layer 200, the first electrodes 310, 320, and 330, the insulating layers 510, 520, and 530, the bank 600, the light emitting layer 700, the second electrode 800, the encapsulation layer 850, the color filter layer 900, and a condensing lens 1000.

Hereinafter, components that are the same as or correspond to the first display area PA1 are denoted by the same reference numerals, and overlapping descriptions thereof will be omitted. For example, in the second display area PA2, the distance between the first lower electrode 311 and the first upper electrode 312 in the first sub-pixel P1, the distance between the second lower electrode 321 and the second upper electrode 322 in the second sub-pixel P2, and the distance between the third lower electrode 331 and the third upper electrode 332 in the third sub-pixel P3 can all be different, and thus it is possible to achieve the micro-cavity effect for each of the different colors of light.

The second display area PA2 has substantially the same emission areas EA1, EA2, and EA3 as the first display area PA1, and an area above the color filter layer 900 in which light is actually emitted can be different from the first display area PA1.

The second display area PA2 can include the condensing lens 1000, which can include a plurality of small lenses over each of the sub-pixels. The condensing lens 1000 can serve to refract light emitted from the color filters CF1, CF2 and CF3. The condensing lens 1000 can be formed to correspond to any one of the color filters CF1, CF2 and CF3. The condensing lens 1000 can correct the color sense of the display device and increase lateral brightness, color gamut, and overall light efficiency.

The light emitted from the color filters CF1, CF2 and CF3 can be refracted by the condensing lens 1000 to have a changed traveling direction. Since light should pass through the condensing lens 1000 for refraction, light that does not pass through the condensing lens 1000 may be leaked light from the display device. Therefore, the color filter layer 900 can include the black matrix BM disposed between the first to third color filters CF1, CF2, and CF3. The black matrix BM can serve to prevent light from leaking to an area other than the area in which the condensing lens 1000 is disposed of an upper portion of the color filter layer 900, which can improve image quality.

The condensing lens 1000 can be formed to correspond to any one of the first sub-pixel P1, the second sub-pixel P2, and the third sub-pixel P3. When the condensing lens 1000 is formed to “correspond,” it means that central axes of the condensing lenses 1000 do not need to exactly match central axes of the emission areas EA1, EA2 and EA3 included in the sub-pixels P1, P2 and P3. Specifically, it is sufficient when each of the first to third condensing lenses 1010, 1020 and 1030 can be identified as being present in a different emission area on each of the emission areas EA1, EA2 and EA3. For example, the first to third condensing lenses 1010, 1020 and 1030 can be disposed over the emission areas EA1, EA2 and EA3 included in the sub-pixels P1, P2 and P3, respectively, with a slight shift in a direction towards the first display area PA1.

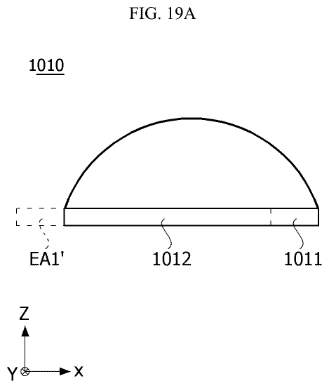

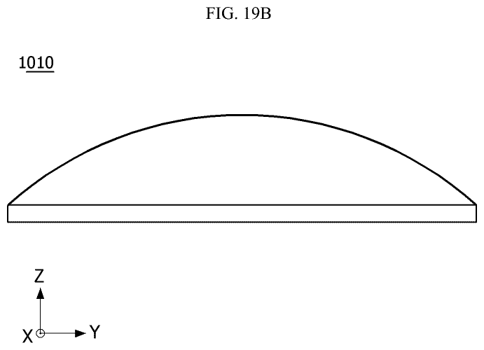

FIGS. 19A and 19B are longitudinal cross-sectional views showing a condensing lens according to one embodiment of the present invention. The following content is described using the first condensing lens 1010 as an example, but it is for convenience of description. Therefore, the following contents, descriptions, and the like can be applied to all condensing lenses according to the present specification.

Referring to FIG. 19A and FIG. 19B, one surface of the condensing lens 1010 can be convex. The condensing lens 1010 can include a convex portion that is convex in a direction (e.g., toward the front surface or upper portion of the display device, or in the Z direction) of the traveling path of the light emitted from the emission area EA1 corresponding to the condensing lens.

The condensing lens 1010 can include a convex portion that is convex in a direction (e.g., toward a back surface or lower portion of the display device) opposite to the traveling path of the light. The condensing lens 1010 has a shape of a convex lens in which both surfaces are convex, thereby increasing condensing efficiency.

Referring to the condensing lens 1010 in the drawing, the condensing lens 1010 can have any curvature in the X-axis direction, the Y-axis direction, and numerous directions between the X-axis and the Y-axis. The curvature can be adjusted to control the amount of collected light. A longitudinal cross-sectional shape of the condensing lens 1010 can be a circle or an ellipse.

Since the condensing lens 1010 is misaligned in the X-axis direction from a first emission area EA1′, it can be inferred that the first display area is disposed in the X-axis direction from the sub-pixel corresponding to the condensing lens 1010. Although there is a height difference between the first emission area EA1′ and the condensing lens 1010 in the Z direction, the height difference in the Z direction is omitted to represent only the relationship in which the first emission area EA1′ is misaligned with the condensing lens 1010 in the X-axis direction.

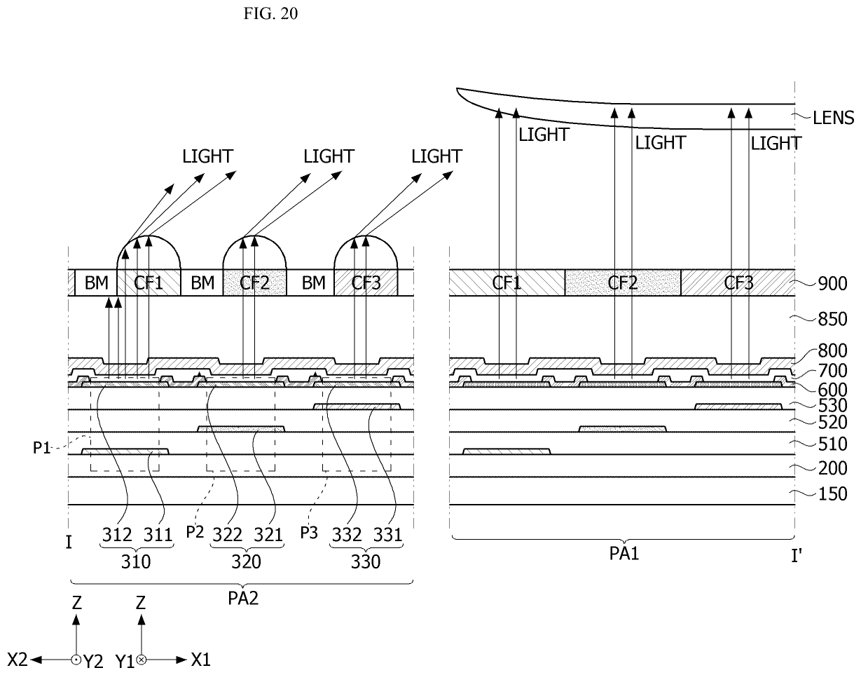

FIG. 20 is a view for describing a traveling direction of light in the first display area and the second display area.

Referring to FIG. 20, the light emitted from the light emitting layer 700 can be emitted in a Lambertian reflection. Light can travel upward (e.g., toward the front surface of the display device) or downward (e.g., toward the back surface of the display device) from the display device. The light emitted downward can eventually travel upward due to the above-described micro-cavity effect. It is possible to increase the luminous efficiency and color gamut of the display device according to the embodiment.

The light emitted from the emission areas EA1, EA2 and EA3 of the first display area PA1 can pass through the color filters CF1, CF2 and CF3, may not be refracted substantially, and can travel to a side at which the eyepiece LENS is disposed. The light emitted from the emission areas EA1, EA2 and EA3 of the first display area PA1 can travel straight without being refracted before reaching the eyepiece LENS.

The light emitted from the emission areas EA1, EA2 and EA3 of the second display area PA2 can be refracted by the condensing lenses 1010, 1020 and 1030 before reaching the eyepiece LENS.

As described above, one or the other surface of the condensing lens can have a convex shape. When there is a difference in refractive index on the traveling path of light, the traveling path can be changed according to Snell's law. Specifically, since a convex lens has the characteristics that the thickness gradually becomes smaller from a central portion to the outside, a normal line to an incident surface of light emitting from the convex lens is directed in a direction in which the thickness of the lens thickness decreases. When the light emitted from the convex lens travels into air or vacuum, the light travels from a high refractive index to a low refractive index, and thus travels in a direction away from the normal line according to Snell's law. Since the condensing lens includes the convex portion, the condensing lens can serve to collect light emitted from the second display area PA2 toward the first display area PA1. Therefore, a refractive index of the condensing lens can be higher than a refractive index of an area outside the condensing lens disposed in the direction in which the light travels from the condensing lens.

As described above, the central portion of the condensing lens 1000 in a cross-sectional view can be shifted toward the first display area PA1. When the central portion of the condensing lens 1000 is not shifted, e.g., substantially half of the light emitted from the first emission area EA1 will travel in a direction away from the first display area PA1, and the remainder will travel in a direction close to the first display area PA1.

In an embodiment, the amount of light that does not travel toward the first display area PA1 can be reduced by shifting the central portion of the condensing lens. Therefore, it is possible to increase the condensing efficiency of light and increase the brightness and viewing angle of the display device including the display panel according to the embodiment from a central portion to a side surface of the display panel, which can improve image quality and provide a better viewing experience, while allowing the device to be thinner.

The condensing lens 1000 can be shifted in the X1, X2, Y1 and Y2 directions in the plan view of the display panel. The amount of light that does not travel toward the first display area PA1 can be controlled by adjusting the shifted distance or length of the condensing lens 1000 in the X1, X2, Y1 and Y2 directions.

Some of the light emitted from the emission areas EA1, EA2 and EA3 can travel to the area other than the area in which the condensing lens 1000 is disposed of the upper portion of the color filter layer 900. The color filter layer 900 of the display areas PA1 and PA2 can include the black matrix BM disposed between the color filters CF1, CF2, and CF3. The black matrix BM can serve to prevent light from leaking to the area other than the area in which the condensing lens 1000 is disposed of the upper portion of the color filter layer 900. Alternatively, the black matrix BM can serve to increase an absorption rate of external light incident from the outside of the display device. Since only a very small amount of incident external light can be reflected by the black matrix BM, it is possible to improve visibility and clarity due to the very small amount of external light.

The black matrix BM is used to decrease contrast caused by bottom reflection of external light and can absorb light in a visible light range. The bottom reflection can indicate that external light is reflected by the lower electrodes 311, 321 and 331.

The condensing lens 1000 can be formed to correspond to at least any one of the first sub-pixel P1, the second sub-pixel P2, and the third sub-pixel P3 and formed adjacent to a light blocking part 51 of each sub-pixel. For example, a first lens 60 can be formed to correspond to the first sub-pixel P1, the second sub-pixel P2, and the third sub-pixel P3.

The black matrix BM can be formed to surround the periphery of each of the sub-pixels P1, P2 and P3 when viewed from the planar direction of the display panel (see FIGS. 5 and 6).

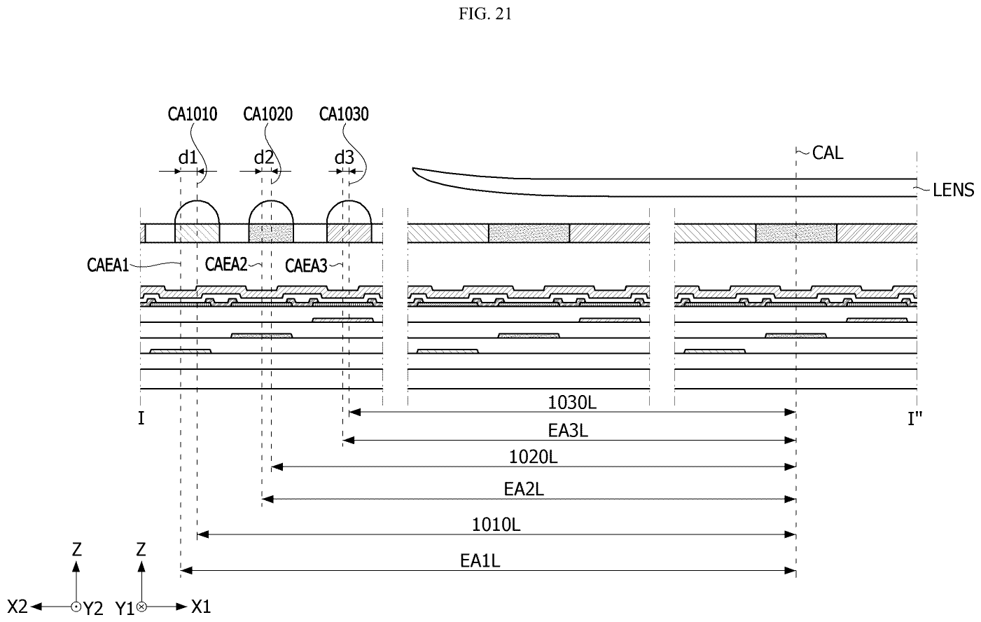

FIG. 21 is a cross-sectional view along line I-I″ in FIG. 17 according to an embodiment of the present invention.

Referring to FIG. 21, a central axis of lens CAL can be defined in the eyepiece LENS. The central axis of the eyepiece CAL can have the relationship substantially perpendicular to the plane on which the display panel is disposed from central portions of the pixels disposed at the central portion among the pixels disposed in the first display area. Alternatively, the central axis of the eyepiece CAL can include the central portions of the pixel arrays corresponding to the user's eyes and can be substantially perpendicular to the plane on which the display panel is disposed. The central axis of the eyepiece CAL can include the central portion of the first display area PA1 and can be substantially the same as a central axis substantially perpendicular to the plane on which the display panel is disposed. The central axis of the eyepiece CAL can be a central axis based on the central portion of the first display area PA1.

In the first condensing lens 1010, a central axis CA1010 of the first condensing lens 1010, which includes the central portion of the first condensing lens 1010 and is substantially perpendicular to the plane on which the display panel is disposed, can be defined. In the second condensing lens 1020, a central axis CA1020 of the second condensing lens 1020, which includes the central portion of the second condensing lens 1020 and is substantially perpendicular to the plane on which the display panel is disposed, can be defined. In the third condensing lens 1030, a central axis CA1030 of the third condensing lens 1030, which includes the central portion of the third condensing lens 1030 and is substantially perpendicular to the plane on which the display panel is disposed, can be defined.

In the first color filter, a central axis of the first color filter, which includes the central portion of the first color filter and is substantially perpendicular to the plane on which the display panel is disposed, can be defined. The first color filter can correspond to the first sub-pixel. The first sub-pixel can include the first emission area. The first emission area can correspond to the first condensing lens. The central axis CA1010 of the first condensing lens can match the central axis of the first color filter corresponding to the first sub-pixel including the first emission area corresponding to the first condensing lens. The central portion of the first condensing lens can overlap with the central portion of the first color filter in the planar direction of the display panel.

In the second color filter, a central axis of the second color filter, which includes the central portion of the second color filter and is substantially perpendicular to the plane on which the display panel is disposed, can be defined. The second color filter can correspond to the second sub-pixel. The second sub-pixel can include the second emission area. The second emission area can correspond to the second condensing lens. The central axis CA1020 of the second condensing lens can match the central axis of the second color filter corresponding to the second sub-pixel including the second emission area corresponding to the second condensing lens. The central portion of the second condensing lens can overlap with the central portion of the second color filter in the planar direction of the display panel.

In the third color filter, a central axis of the third color filter, which includes the central portion of the third color filter and is substantially perpendicular to the plane on which the display panel is disposed, can be defined. The third color filter can correspond to the third sub-pixel. The third sub-pixel can include the third emission area. The third emission area can correspond to the third condensing lens. The central axis CA1030 of the third condensing lens can match the central axis of the third color filter corresponding to the third sub-pixel including the third emission area corresponding to the third condensing lens. The central portion of the third condensing lens can overlap with the central portion of the third color filter in the planar direction of the display panel.

In the first emission area EA1, a central axis CAEA1 of the first emission area, which includes the central portion of the first emission area EA1 and is substantially perpendicular to the plane on which the display panel is disposed, can be defined. In the second emission area EA2, a central axis CAEA2 of the second emission area, which includes the central portion of the second emission area EA2 and is substantially perpendicular to the plane on which the display panel is disposed, can be defined. In the third emission area EA3, a central axis CAEA3 of the third emission area, which includes the central portion of the third emission area EA3 and is substantially perpendicular to the plane on which the display panel is disposed, can be defined.

The central axis CA1010 of the first condensing lens can be misaligned with the central axis CAEA1 of the first emission area EA1 corresponding to the first condensing lens. The central axis CA1020 of the second condensing lens can be misaligned with the central axis CAEA2 of the second emission area EA2 corresponding to the second condensing lens. The central axis CA1030 of the third condensing lens can be misaligned with the central axis CAEA3 of the third emission area EA3 corresponding to the third condensing lens. In other words, the condensing lenses can be slightly shifted closer to the first display area PA1 relative to their corresponding emission areas.

In the plan view of the display panel, the central axis CA1010 of the first condensing lens may not match the central axis CAEA1 of the first emission area EA1 corresponding to the first condensing lens. In the plan view of the display panel, the central axis CA1020 of the second condensing lens may not match the central axis CAEA2 of the second emission area EA2 corresponding to the second condensing lens. In the plan view of the display panel, the central axis CA1030 of the third condensing lens may not match the central axis CAEA3 of the third emission area EA3 corresponding to the third condensing lens.

A minimum distance 1010L between the central axis of lens CAL based on the central portion of the first display area and the central axis CA1010 of the first condensing lens can be smaller than a minimum distance EA1L between the central axis of lens CAL based on the central portion of the first display area and the central axis CAEA1 of the first emission area EA1 corresponding to the first condensing lens.

A minimum distance 1020L between the central axis of lens CAL based on the central portion of the first display area and the central axis CA1020 of the second condensing lens can be smaller than a minimum distance EA2L between the central axis of lens CAL based on the central portion of the first display area and the central axis CAEA2 of the second emission area EA2 corresponding to the second condensing lens.

A minimum distance 1030L between the central axis of lens CAL based on the central portion of the first display area and the central axis CA1030 of the third condensing lens can be smaller than a minimum distance EA3L between the central axis of lens CAL based on the central portion of the first display area and the central axis CAEA3 of the third emission area EA3 corresponding to the third condensing lens.

A first difference d1 between the minimum distance 1010L between the central axis of lens CAL based on the central portion of the first display area and the central axis CA1010 of the first condensing lens and the minimum distance EA1L between the central axis of lens CAL based on the central portion of the first display area and the central axis CAEA1 of the first emission area EA1 corresponding to the first condensing lens can indicate a shifted distance or length of the central portion of the first condensing lens to the side at which the first display area is disposed.

A second difference d2 between the minimum distance 1020L between the central axis of lens CAL based on the central portion of the first display area and the central axis CA1020 of the second condensing lens and the minimum distance EA2L between the central axis of lens CAL based on the central portion of the first display area and the central axis CAEA2 of the second emission area EA2 corresponding to the second condensing lens can indicate a shifted distance or length of the central portion of the second condensing lens to the side at which the first display area is disposed.

A third difference d3 between the minimum distance 1030L between the central axis of lens CAL based on the central portion of the first display area and the central axis CA1030 of the third condensing lens and the minimum distance EA3L between the central axis of lens CAL based on the central portion of the first display area and the central axis CAEA3 of the third emission area EA3 corresponding to the third condensing lens can indicate a shifted distance or length of the central portion of the third condensing lens to the side at which the first display area is disposed.

The display device according to the embodiment can have the tendency that the farther the condensing lens is disposed away from the first display area, the greater the shifted length of the condensing lens is. The first difference d1 can be greater than the second difference d2, and the second difference d2 can be greater than the third difference d3 (e.g., d1>d2>d3). The tendency can be not only applied to the shifted lengths of the plurality of condensing lenses included in one pixel, but also the plurality of condensing lenses included in different pixels. For example, a shifted length of the condensing lens included in a pixel disposed relatively away from the first display area PA1 can be greater than a shifted length of the condensing lens included in a pixel disposed relatively close to the first display area PA1. In other words, the farther a sub-pixel is away from the first display area PA1, then its corresponding condensing lens will be shifted by an even greater distance towards first display area PA1.

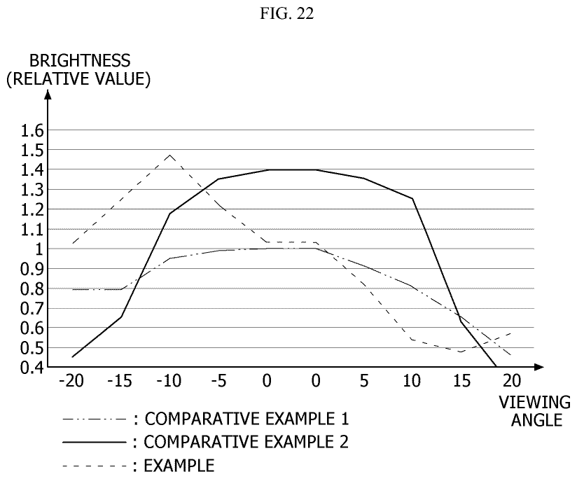

FIG. 22 is a simulation graph showing a brightness relative value of the display panel according to one embodiment.

Referring to FIG. 22, a viewing angle is an angle at which the user's eyes see each of the display panels 100A and 100B with respect to a center position O of the first display area PA1 substantially corresponding to center positions of the user's eyes.

A simulation graph of Comparative Example 1 is obtained by measuring the brightness (relative value) of the display panel according to the user's viewing angle when the condensing lens is not disposed in the second display area PA2 (e.g., no condensing lenses in the second display area PA2).

A simulation graph of Comparative Example 2 is obtained by measuring the brightness (relative value) of the display panel according to the user's viewing angle when the condensing lens is disposed in the second display area PA2 and the central axis of the condensing lens is aligned or matched with the central axis of the emission area corresponding to the condensing lens. In other words, Comparative Example 2 is a simulation graph measured when the central axes of the condensing lens and the emission area are aligned to match each other (e.g., no shifting of the condensing lenses).

A simulation graph of Example is obtained by measuring the brightness (relative value) of the display panel according to the user's viewing angle when the condensing lens is disposed in the second display area PA2 and the central axis of the condensing lens is misaligned with the central axis of the emission area corresponding to the condensing lens (e.g., condensing lenses in the second display area PA2 are slight shifted towards the first display area PA1).

When comparing Comparative Example 1 with Comparative Example 2 and the Example, it was confirmed that the overall brightness was improved at the measured viewing angle.

When comparing the Example with Comparative Example 2, it can be seen that as the viewing angle increases, the brightness relatively increases compared to that of Comparative Example 2. From the simulation graph shown, as lateral brightness is increased according to the Example, it is possible to decrease a deviation of the brightness of light incident on the eyepiece, and image quality can be improved.

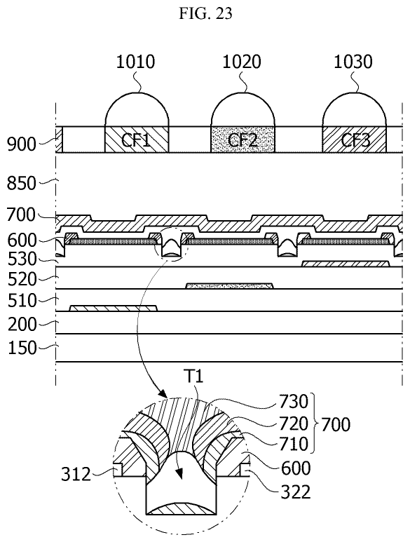

FIG. 23 is a first modified example of the display panel according to one embodiment of the present invention. The same components are denoted by the same reference numerals, and descriptions thereof are omitted. Hereinafter, only different components will be described.

Referring to FIG. 23, a first trench T1 can be formed in boundary areas between the plurality of sub-pixels P1, P2 and P3. A current path between adjacent sub-pixels P1, P2 and P3 can be formed to be relatively longer due to the first trench T1 than that of a situation without the trench. Therefore, it is possible to reduce a leakage current generated between adjacent sub-pixels P1, P2 and P3.

Since the first trench T1 is disposed in the bank 600 and the third insulating layer 530, the light emitting layer 700 can be formed in the first trench T1. The current path can be formed to be relatively long between the adjacent sub-pixels P1, P2 and P3. Therefore, it is possible to reduce a leakage current generated between the adjacent sub-pixels P1, P2 and P3. More specifically, it is possible to reduce a lateral leakage current LLC generated at the side surfaces of the sub-pixels P1, P2 and P3.

When a distance between the sub-pixels P1, P2 and P3 is densely configured to implement a high resolution, light can be emitted from the light emitting layer 700 in any one of the sub-pixels P1, P2 and P3, and charges in the light emitting layer 700 can move to the light emitting layer 700 in another sub-pixel of the sub-pixels P1, P2 and P3. Therefore, there is a possibility that a leakage current is generated. For example, when resolution is increase and sub-pixels are packed more closely together, then leakage current can become more of a risk.

Therefore, by arranging the first trench T1 at the boundaries between the sub-pixels P1, P2 and P3 and forming the light emitting layer 700 in the first trench T1, a much longer current path between the adjacent sub-pixels P1, P2 and P3 can be formed. With this configuration, a resistance can be increased in a traveling direction (substantially opposite to the moving direction of the current) of the charges. Therefore, it is possible to reduce the leakage current, save power and improve image quality.

The first trench T1 may not be formed in the third insulating layer 530 and can be formed only in the bank 600 according to an embodiment.

The first trench T1 can extend to the inside of the second insulating layer 520, the inside of the first insulating layer 510, or the inside of the circuit element layer 200, which is formed thereunder as well as extending to the bank 600 and the third insulating layer 530.

Referring to the enlarged view of FIG. 23, the light emitting layer 700 can include a first stack 710 that emits light of a first color, a second stack 730 that emits light of a second color, and a charge generation layer 720 provided between the first stack 710 and the second stack 730.

The first stack 710 can be formed on an inner side surface of the first trench T1 and can also be formed on an inner lower surface of the first trench T1. A portion of the first stack 710 formed on the inner side surface of the first trench T1 and a portion of the first stack 710 formed on the inner lower surface of the first trench T1 can be separated without being connected to each other. A portion of the first stack 710 formed on one inner side surface, for example, an inner left side surface of the first stack 710 and a portion of the first stack 710 formed on the other inner side surface, for example, a right side surface of the first trench T1 can be separated without being connected to each other. Therefore, the charges may not move through the first stack 710 between the sub-pixels P1, P2 and P3 disposed adjacent to each other with the first trench T1 interposed therebetween.

The charge generation layer 720 can be formed on the first stack 710 on the inner side surface of the first trench T1. In this situation, a portion of the charge generation layer 720 formed on the one inner side surface, for example, the inner left side surface of the first trench T1 and a portion of the charge generation layer 720 formed on the other inner side surface, for example, the inner right side surface of the first trench T1 can be separated without being connected to each other. Therefore, the charges may not move through the charge generation layer 720 between the sub-pixels P1, P2 and P3 disposed adjacently with the first trench T1 interposed therebetween.

The second stacks 730 can be connected without being separated between the sub-pixels P1, P2 and P3 disposed adjacent to each other with the first trench T1 interposed therebetween on the charge generation layer 720. The charges can move through the second stack 730 between the sub-pixels P1, P2 and P3 disposed adjacent to each other with the first trench T1 interposed therebetween. However, the present invention is not necessarily limited thereto, and the embodiment can be configured so that by appropriately adjusting the shape of the first trench T1 and the deposition process of the light emitting layer 700, the second stacks 730 are separated between the sub-pixels P1, P2 and P3 disposed adjacent to each other with the first trench T1 interposed therebetween. A portion of a lower portion of the second stack 730 adjacent to the charge generation layer 720 can be separated in the area between the sub-pixels P1, P2 and P3.

The charge generation layer 720 can have greater conductivity than the first stack 710 and the second stack 730. Since the N-type charge generation layer forming the charge generation layer 720 can include a metal material, the N-type charge generation layer can have greater conductivity than the first stack 710 and the second stack 730. Therefore, the movement of the charges between the sub-pixels P1, P2 and P3 disposed adjacent to each other mainly occurs through the charge generation layer 720, and the moving amounts of charges through the second stack 730 can be relatively small.

When the light emitting layer 700 is formed in the first trench T1, a portion of the light emitting layer 700 can be formed to be separated in the first trench T1. By separately forming the first stack 710 and the charge generation layer 720, it is possible to reduce the leakage current generated between the adjacent sub-pixels P1, P2, and P3.

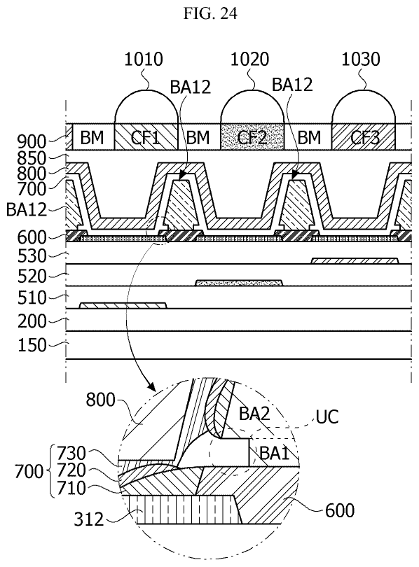

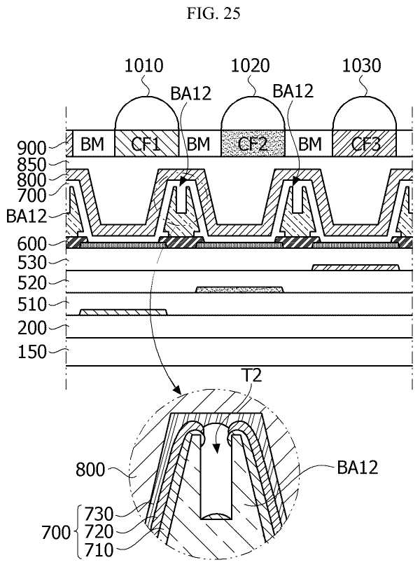

FIGS. 24 and 25 show a display device that differs from the display device according to FIG. 23 in that bank structures BA1 and BA2 including an undercut-shaped side portion can be formed on the banks 600 disposed at the boundaries between the plurality of sub-pixels P1, P2 and P3. The bank structures BA1 and BA2 are each denoted by different reference numerals in that the first bank structure BA1 and the second bank structure BA2 can be formed separately in the manufacturing process, but hereinafter, can be collectively referred to as a bank structure BA12. For example, bank structure BA2 can be stacked on or disposed on bank structure BA1 to form the overall bank structure BA12.

FIG. 24 is a second modified example of the display panel according to one embodiment of the present invention. The same components are denoted by the same reference numerals, and descriptions thereof are omitted. Hereinafter, only different components will be described.

Referring to FIG. 24, the bank structure BA12 disposed on the bank 600 can be provided. The bank structure BA12 can have a form in which the first bank structure BA1 and the second bank structure BA2 are stacked sequentially.

The second bank structure BA2 can have a tapered or reverse tapered shape. Regardless of the shape of the second bank structure BA2, the first bank structure BA1 can be in contact with the second bank structure BA2 with an area smaller than a bottom surface of the second bank structure BA2. Side portions BAS of the bank structures BA1 and BA2 can have an undercut (UC) shape. The light emitting layer 700, the second electrode 800, and the encapsulation layer 850 can be sequentially stacked on the second bank structure BA2.

Referring to the enlarged view of FIG. 24, the light emitting layer 700 can include the first stack 710 that emits light of the first color, the second stack 730 that emits light of the second color, and the charge generation layer 720 provided between the first stack 710 and the second stack 730.

The first stack 710 can be formed above the second bank structure BA2 or above the first upper electrodes 312, 322, and 332. A portion of the first stack 710 formed on the second bank structure BA2 and a portion of the first stack 710 formed on the first upper electrodes 312, 322, and 332 can be separated without being connected to each other. Therefore, the charges may not move through the first stack 710 between the sub-pixels P1, P2, and P3 disposed adjacent to each other with the bank structures BA1 and BA2 interposed therebetween. In other words, the light emitting layer 700 can be entirely cut or partially cut by the undercut portion of the bank structure BA12, e.g., bank structure BA2 can overhang bank structure BA1 by a certain distance to form an eave or undercut portion.

The charge generation layer 720 can be formed above the first stack 710. A portion of the charge generation layer 720 disposed on the second bank structure BA2 and a portion of the charge generation layer 720 disposed on the first upper electrodes 312, 322 and 332 can be separated without being connected to each other. Therefore, the charges may not move through the charge generation layer 720 between the sub-pixels P1, P2 and P3 disposed adjacent to each other with the bank structure BA12 interposed therebetween.

The second stack 730 can be connected without being separated between the sub-pixels P1, P2, and P3 disposed adjacent to each other with the bank structure BA1 and BA2 interposed therebetween on the charge generation layer 720. The charges can move through the second stack 730 between the sub-pixels P1, P2, and P3 disposed adjacent to each other with the bank structure BA12 interposed therebetween. However, the present invention is not necessarily limited thereto, and the embodiment can be configured so that by appropriately adjusting an etching process (e.g., dry etching) of the first bank structure BA1 for adjusting the undercut shape and the deposition process of the light emitting layer 700, the second stack 730 is separated between the sub-pixels P1, P2 and P3 disposed adjacent to each other with the bank structures BA1 and BA2 interposed therebetween. The portion of the lower portion of the second stack 730 adjacent to the charge generation layer 720 can be separated in the area between the sub-pixels P1, P2 and P3.

The charge generation layer 720 can have greater conductivity than the first stack 710 and the second stack 730. Since the N-type charge generation layer forming the charge generation layer 720 can include a metal material, the N-type charge generation layer can have greater conductivity than the first stack 710 and the second stack 730. Therefore, the movement of the charges between the sub-pixels P1, P2 and P3 disposed adjacent to each other mainly occurs through the charge generation layer 720, and the moving amounts of charges through the second stack 730 can be relatively small.

FIG. 25 is a third modified example of the display panel according to one embodiment of the present invention. The same components are denoted by the same reference numerals, and descriptions thereof are omitted. Hereinafter, only different components will be described.

Referring to FIG. 25, a second trench T2 can be formed in an upper portion of the bank structure BA12. A current path between adjacent sub-pixels P1, P2 and P3 can be formed to be even longer by the second trench T2 than that of a situation without the trench. Therefore, it is possible to further reduce a leakage current generated between adjacent sub-pixels P1, P2 and P3.

Since the second trench T2 is disposed in the bank 600, the light emitting layer 700 can be formed in the second trench T2. The current path can be formed to be relatively long between the adjacent sub-pixels P1, P2 and P3. In other words, similar to the first trench T1 in the third insulating layer 530, the second trench T2 can cut the light emitting layer 700. Therefore, it is possible to further reduce a leakage current generated between the adjacent sub-pixels P1, P2 and P3. More specifically, it is possible to reduce a lateral leakage current LLC generated at the side surfaces of the sub-pixels P1, P2 and P3.

When a distance between the sub-pixels P1, P2, and P3 is very small and the sub-pixels are packed densely together to implement a high resolution, light can be emitted from the light emitting layer 700 in any one of the sub-pixels P1, P2 and P3, and charges in the light emitting layer 700 may move to the light emitting layer 700 in another sub-pixel of the sub-pixels P1, P2 and P3. Therefore, there is a risk that a leakage current is generated.

Therefore, by arranging the second trench T2 in upper portions of the bank structures BA12 between the sub-pixels P1, P2, and P3 and forming the light emitting layer 700 in the second trench T2, the long current path between the adjacent sub-pixels P1, P2, and P3 can be formed. With this configuration, a resistance can be increased in the traveling direction (substantially opposite to the moving direction of the current) of the charges. Therefore, it is possible to reduce the leakage current.

Referring to the enlarged view of FIG. 25, the light emitting layer 700 can include the first stack 710 that emits light of the first color, the second stack 730 that emits light of the second color, and the charge generation layer 720 provided between the first stack 710 and the second stack 730.

The first stack 710 can be formed on an inner side surface of the second trench T2 and can also be formed on an inner lower surface of the second trench T2. A portion of the first stack 710 formed on the inner side surface of the second trench T2 and a portion of the first stack 710 formed on the inner lower surface of the second trench T2 can be separated without being connected to each other (e.g., the first stack 710 can be cut by the second trench T2). A portion of the first stack 710 formed on one inner side surface, e.g., an inner left side surface of the second trench T2 and a portion of the first stack 710 formed on the other inner side surface, e.g., a right side surface of the second trench T2 can be separated without being connected to each other. Therefore, the charges may not move through the first stack 710 between the sub-pixels P1, P2 and P3 disposed adjacent to each other with the second trench T2 interposed therebetween.

The charge generation layer 720 can be formed on the first stack 710 on the inner side surface of the second trench T2. In this situation, a portion of the charge generation layer 720 formed on the one inner side surface, e.g., the inner left side surface of the second trench T2 and a portion of the charge generation layer 720 formed on the other inner side surface, e.g., the inner right side surface of the second trench T2 can be separated without being connected to each other (e.g., the charge generation layer 720 can be cut by the second trench T2). Therefore, the charges may not move through the charge generation layer 720 between the sub-pixels P1, P2 and P3 disposed adjacent to each other with the second trench T2 interposed therebetween.

The second stack 730 can be connected without being separated between the sub-pixels P1, P2, and P3 disposed adjacent to each other with the second trench T2 interposed therebetween on the charge generation layer 720 (e.g., the second stack 730 can extend across the second trench T2). The charges can move through the second stack 730 between the sub-pixels P1, P2 and P3 disposed adjacent to each other with the second trench T2 interposed therebetween. However, the present invention is not necessarily limited thereto, and the embodiment can be configured so that, by appropriately adjusting the shape of the second trench T2 and the deposition process of the light emitting layer 700, the second stack 730 can separated between each of the sub-pixels P1, P2 and P3 disposed adjacent to each other with the second trench T2 interposed therebetween. The portion of the lower portion of the second stack 730 adjacent to the charge generation layer 720 can be separated in the area between the sub-pixels P1, P2 and P3 (e.g., the second stack 730 can be cut by the second trench T2).

The charge generation layer 720 can have greater conductivity than the first stack 710 and the second stack 730. Since the N-type charge generation layer forming the charge generation layer 720 can include a metal material, the N-type charge generation layer can have greater conductivity than the first stack 710 and the second stack 730. Therefore, the movement of the charges between the sub-pixels P1, P2 and P3 disposed adjacent to each other mainly occurs through the charge generation layer 720, and the moving amounts of charges through the second stack 730 can be relatively small.

When the light emitting layer 700 is formed in the second trench T2, a portion of the light emitting layer 700 can be formed to be separated in the second trench T2. By separately forming the first stack 710 and the charge generation layer 720, it is possible to reduce the leakage current generated between the adjacent sub-pixels P1, P2 and P3.

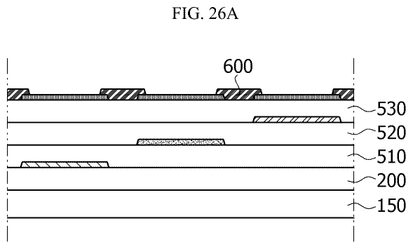

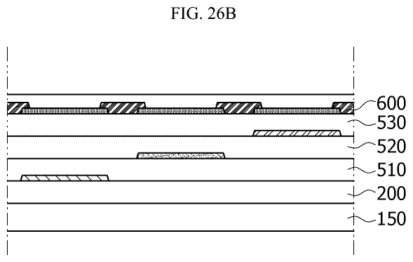

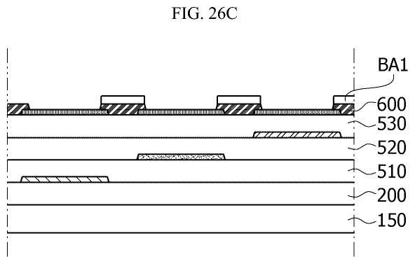

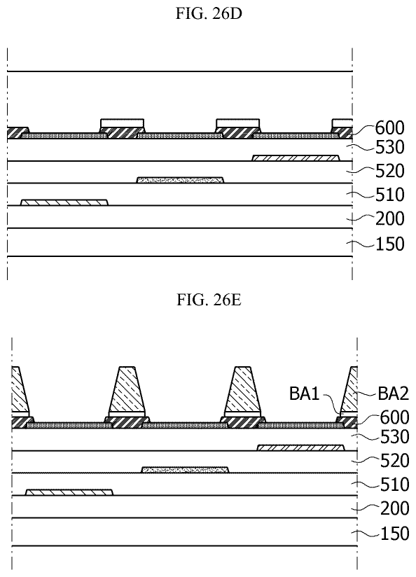

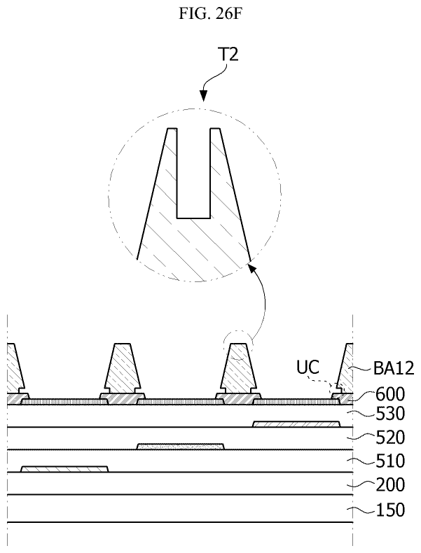

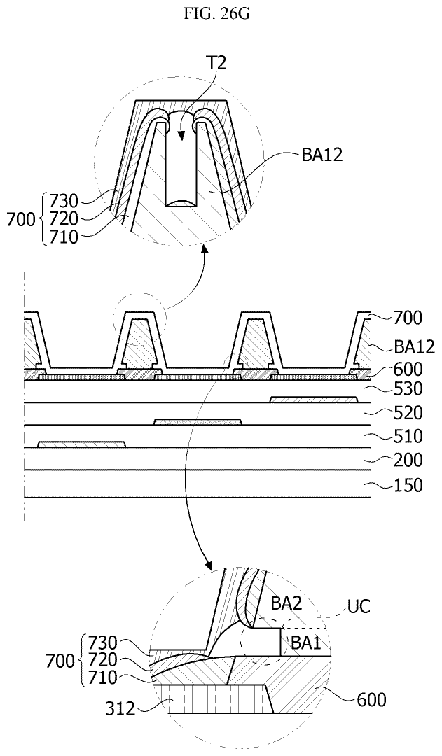

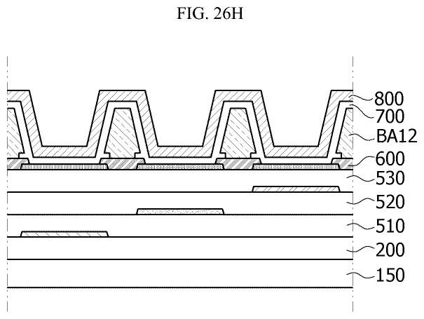

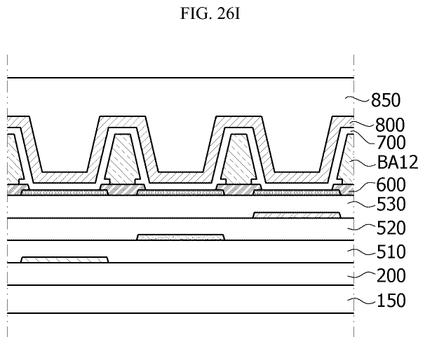

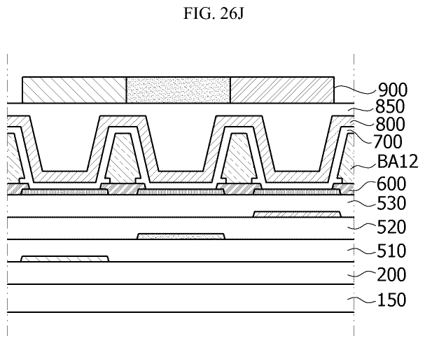

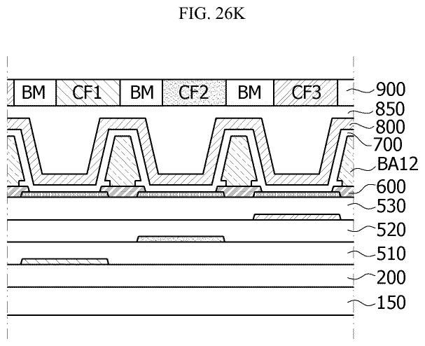

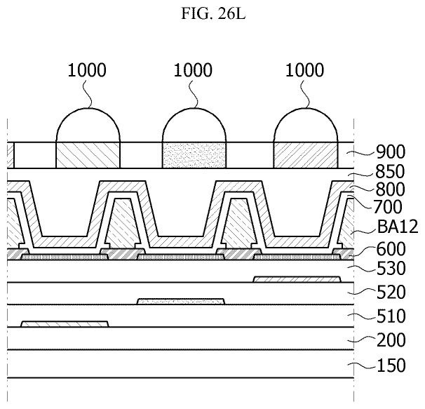

FIGS. 26A to 26I are schematic cross-sectional views showing processes of manufacturing the second and third modified examples of the display panel.

Referring to FIG. 26A, a process of forming the bank 600 to cover the ends of the upper electrodes 312, 322, and 332 is performed.

Referring to FIGS. 26B and 26C, a process of coating the upper portions of the bank 600 and the upper electrodes 312, 322 and 332, and patterning the first bank structure BA1 to form the first bank structure BA1 is performed.

Referring to FIGS. 26D and 26E, a process of coating the upper portions of the first bank structure BA1 and the upper electrodes 312, 322 and 332, and patterning the second bank structure BA2 to form the second bank structure BA2 is performed.

Referring to FIG. 26F, a process of etching side portions of the bank structure BA12 so that the side portions of the bank structure BA12 have an undercut (UC) shape is performed. Referring to the enlarged view of FIG. 26F, after performing the above process, a process for forming the second trench T2 in the upper portion of the bank structure BA12 can be performed additionally.

Referring to FIG. 26G, a deposition process is performed to form the light emitting layer 700. In this process, at least one or more of the first stack, the charge generation layer, and the second stack can be separated into a plurality of pieces without being connected to each other due to the previously formed undercut and/or second trench. The enlarged views of FIG. 26G are substantially the same as those described above with reference to FIGS. 24 and 25. For example, the first stack 710, the charge generation layer 720, and the second stack 730 can be sequentially stacked in the deposition process of the light emitting layer 700.

Referring to FIG. 26H, a deposition process is performed to form the second electrode 800.

Referring to FIG. 26I, a deposition process is performed to form the encapsulation layer 850.

Referring to FIG. 26J, a process of patterning a photosensitive resin composition is performed to form the color filter layer 900. In forming the color filter layer 900, the central axis of each of the color filters can be formed to be misaligned with the central axis of the emission area (e.g., slightly shifted toward the first display area PA1).

Referring to FIG. 26K, a process of forming the black matrix BM between the color filters CF1, CF2 and CF3 is performed.

Referring to FIG. 26L, a process of forming the condensing lens 1000 on the color filter layer is performed. The central portion or central axis of the condensing lens 1000 can be formed on the color filter layer so that each condensing lens is misaligned with the central axis of the corresponding emission area (e.g., slightly shifted toward the first display area PA1). In an embodiment, after the central axes or central portions of the color filter layer 900 and the condensing lens 1000 are all formed to overlap with the central axes or central portions of the emission areas in the planar direction of the display panel, the color filter layer 900 and the condensing lens 1000 can be moved at the same time so that the central axes or central portions of the color filter layer 900 and the condensing lens 1000 are misaligned with the central axes or central portions of the emission areas.

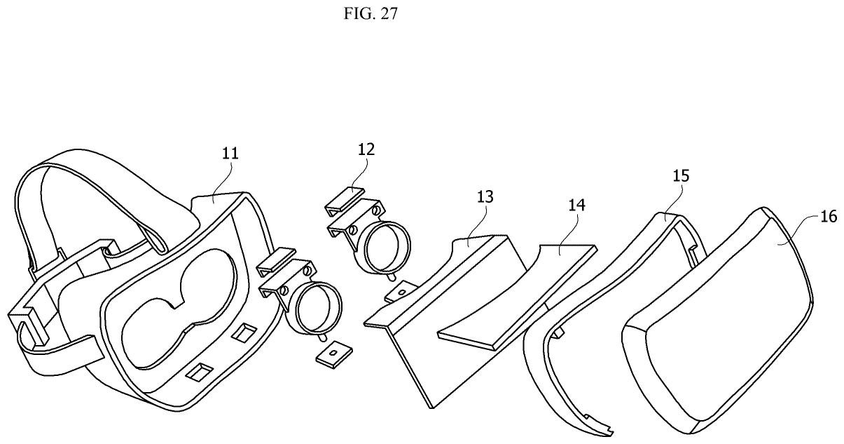

FIG. 27 is an exploded perspective view showing a personal immersion device according to one embodiment of the present invention.

Referring to FIG. 27, the personal immersion display device can include a lens module 12, a display module 13, a main board 14, a head gear 11, a side frame 15, a front cover 16, and the like.

The display module 13 can include a display panel driving circuit for driving each of two display panels and display input images received from the main board 14. The display panels can be partitioned into a first display panel visible to the user's left eye and a second display panel visible to the user's right eye. The display module can display image data input from the main board on the display panels. The image data can be two-dimensional (2D) or three-dimensional (3D) image data that implements video images of virtual reality (VR) or augmented reality (AR). The display module 13 can display various pieces of information input from the main board in a form of texts, symbols, or the like.

The lens module 12 can include an ultra-wide-angle lens, that is, a pair of eyepieces LENS (Fisheye lens) for expanding an angle of view of the user's left and right eyes. The pair of eyepieces LENS can include a left-eye lens disposed in front of the first display panel and a right-eye lens disposed in front of the second display panel.

The main board 14 can include a processor for executing VR software and supplying a left-eye image and a right-eye image to the display module 13. In addition, the main board 14 can further include an interface module, a sensor module, and the like that are connected to an external device. The interface module can be connected to the external device through an interface, such as a universal serial bus (USB) or a high definition multimedia interface (HDMI). The sensor module can include various sensors, such as a gyro sensor and an acceleration sensor. The processor of the main board 14 can correct the left-eye and right-eye image data in response to an output signal of the sensor module and transmit the left-eye and right-eye image data of the input image received through the interface module to the display module 13. The processor can generate a left-eye image and a right-eye image that match the resolution of the display panel based on depth information analysis results of the 2D images and transmit the left-eye image and the right-eye image to the display module 13.

The head gear 11 can include a back cover exposing the eyepieces LENS and a band connected to the back cover. The back cover of the head gear 11, the side frame 15, and the front cover 16 can be assembled to secure an internal space in which the components of the personal immersion device are disposed and protect the components. The components can include the lens module 12, the display module 13, and the main board 14. The band can be connected to the back cover. The user can wear the personal immersion device on his/her head with the band. When wearing the personal immersion device on his/her head, the user can see different display panels with his/her left and right eyes through eyepieces LENS.

The side frame 15 can be fixed between the head gear 11 and the front cover 16 to secure a gap in the internal space in which the lens module 12, the display module 13, and the main board 14 are disposed. The front cover 16 can be disposed on a front surface of the personal immersion device.

The personal immersion device according to the present invention can be implemented in a head mounted display (HMD) structure, but is not limited thereto. For example, the present invention can be designed as an eye glasses-type display (EGD) device with a glasses structure, a face mounted display (FMD) device, or the like, which is worn on the face.

A display panel according to the present specification can increase luminous efficiency, thereby implementing low-power driving, while also providing a thinner and more compact design that can be easier for the user to wear.

The display panel according to the present specification can improve a color gamut and external light extraction efficiency.

The display panel according to the present specification can improve condensing efficiency, thereby correcting a color sense and increasing brightness.

The display panel according to the present specification can decrease a current leakage through a side surface thereof, thereby decreasing overall power consumption.

Since the contents of the specification described in the above-described technical problem, technical solution, and advantageous effects do not specify the essential features of the claims, the scope of the claims is not limited by the items described in the contents of the specification.

Although embodiments of the present invention have been described in more detail with reference to the accompanying drawings, the present invention is not necessarily limited to the embodiments, and various modifications can be carried out without departing from the technical spirit of the present invention. Therefore, the embodiments disclosed in the present invention are not intended to limit the technical spirit of the present invention, but are intended to describe the same, and the scope of the technical spirit of the present invention is not limited by the embodiments. Therefore, it should be understood that the above-described embodiments are illustrative and not restrictive in all respects. The scope of the present invention should be construed according to the appended claims, and all technical spirits within the equivalent range should be construed as being included in the scope of the present invention.

What is claimed is:

1. A display panel comprising:
a first plurality of sub-pixels disposed on a substrate in a first display area, and a second plurality of sub-pixels disposed on the substrate in a second display area surrounding the first display area;
a light emitting layer configured to emit light in each of the first plurality of sub-pixels and the second plurality of sub-pixels;
a color filter layer disposed on the light emitting layer; and
a plurality of condensing lenses disposed on the color filter layer in the second display area,
wherein the plurality of condensing lenses are disposed to correspond one-to-one to emission areas of the second plurality of sub-pixels disposed in the second display area, and
wherein a central axis of each of the plurality of condensing lenses in the second display area is misaligned with a central axis of a corresponding emission area among the emission areas.

2. The display panel of claim 1, wherein the first display area includes a first side surface and a second side surface opposite to each other and a third side surface and a fourth side surface opposite to each other,
wherein the second display area includes a 2-1 display area adjacent to the first side surface, a 2-2 display area adjacent to the second side surface, a 2-3 display area adjacent to the third side surface, and a 2-4 display area adjacent to the fourth side surface, and
wherein central axes of a first group of condensing lenses among the plurality of condensing lenses disposed in the 2-1 display area and central axes of a second group of condensing lenses among the plurality of condensing lenses disposed in the 2-2 display area are misaligned with central axes of the corresponding emission areas and closer to the first display area.

3. The display panel of claim 1, wherein a minimum distance between a central axis based on a central portion of the first display area and a central axis of at least one condensing lens among the plurality of condensing lenses is smaller than a minimum distance between the central axis based on the central portion of the first display area and a central axis of an emission area corresponding to the at least one condensing lens.

4. The display panel of claim 1, wherein a first orthogonally projected area in which at least one condensing lens among the plurality of condensing lenses is orthogonally projected onto a plane including an emission area corresponding to the at least one condensing lens includes a 1-2 orthogonally projected area overlapping with the emission area and a 1-1 orthogonally projected area corresponding to a remaining portion of the first orthogonally projected area excluding the 1-2 orthogonally projected area, and
wherein an area of the 1-2 orthogonally projected area is greater than an area of the 1-1 orthogonally projected area.

5. The display panel of claim 1, wherein a central axis of at least one condensing lens among the plurality of condensing lenses is shifted closer toward the first display area than a central axis of an emission area corresponding to the at least one condensing lens, in a planar direction of the emission area.

6. The display panel of claim 5, wherein the color filter layer includes a plurality of color filters disposed to correspond one-to-one to the second plurality of sub-pixels in the second display area, and a black matrix disposed between the plurality of color filters, and
wherein the plurality of color filters are shifted closer the first display area than emission areas of the second plurality of sub-pixels.

7. The display panel of claim 6, wherein condensing lenses of sub-pixels located farther away from the first display area are shifted by greater distances relative to corresponding emission areas than condensing lenses of sub-pixels that are located closer to the first display than the sub-pixels located farther away.

8. The display panel of claim 6, wherein central portions of the plurality of color filters overlap with central portions of the plurality of condensing lenses in the second display area.

9. The display panel of claim 6, wherein the plurality of sub-pixels include first, second and third sub-pixels,
wherein the plurality of color filters include first, second and third color filters corresponding to the first, second and third sub-pixels, respectively,
wherein the plurality of condensing lenses include first, second and third condensing lenses corresponding to the first, second and third sub-pixels, respectively, and
wherein central portions of the first, second and third condensing lenses correspond to central portions of the first, second and third color filters.

10. The display panel of claim 1, wherein each of the plurality of condensing lenses has a semi-circular cross section or a semi-elliptical cross section, and
wherein a refractive index of the plurality of condensing lenses is higher than a refractive index of an area over the plurality of condensing lenses.

11. The display panel of claim 1, wherein the first display area is configured to emit light that travels in a straight direction or in a direction perpendicular to the substrate, and
wherein the second display area is configured to emit light that is refracted by the plurality of condensing lenses or emit light in a diagonal direction relative to the substrate.

12. The display panel of claim 1, further comprising:
a circuit element disposed between the substrate and the light emitting layer;
a first electrode disposed between the circuit element and the light emitting layer;
a bank overlapping with an end of the first electrode; and
a second electrode disposed between the light emitting layer and the color filter layer,
wherein the light emitting layer includes a first stack between the first electrode and the second electrode and configured to emit light of a first color, a second stack disposed on the first stack and configured to emit light of a second color, and a charge generation layer disposed between the first stack and the second stack.

13. The display panel of claim 12, wherein the plurality of sub-pixels include first, second and third sub-pixels,
wherein the bank includes a first trench disposed in boundary areas between the first, second and third sub-pixels, and
wherein the first stack and the charge generation layer are partitioned into a plurality of pieces by the first trench.

14. The display panel of claim 12, wherein the plurality of sub-pixels include first, second and third sub-pixels, and
wherein the display panel further includes a bank structure disposed on the bank, the bank structure having side portions forming an undercut area or eaves.

15. The display panel of claim 14, wherein the first stack and the charge generation layer are partitioned into a plurality of pieces by the bank structure.

16. The display panel of claim 14, further comprising a second trench in an upper portion of the bank structure.

17. The display panel of claim 16, wherein the light emitting layer is disposed on the bank structure, and
wherein the first stack and the charge generation layer are partitioned into a plurality of pieces by the second trench.

18. A display device comprising:
a display panel including a plurality of data lines, a plurality of gate lines, and a plurality of sub-pixels disposed on a substrate; and
a display driver configured to write data to the display panel and drive the display panel,
wherein the display panel further includes:
a first plurality of sub-pixels among the plurality of sub-pixels disposed in a first display area, and a second plurality of sub-pixels among the plurality of sub-pixels disposed in a second display area surrounding the first display area;
a light emitting layer configured to emit light in each of the first plurality of sub-pixels and the second plurality of sub-pixels;
a color filter layer disposed on the light emitting layer; and
a plurality of condensing lenses disposed on the color filter layer in the second display area,
wherein the plurality of condensing lenses correspond to emission areas of the second plurality of sub-pixels, respectively, and
wherein a central axis of each of the plurality of condensing lenses in the second display area is misaligned with a central axis of a corresponding emission area among the emission areas.

19. A personal immersion device comprising:
a first display panel configured to display a left-eye image;
a second display panel configured to display a right-eye image;
a first drive integrated circuit configured to convert pixel data of the left-eye image into first data voltages and supply the first data voltages to first data lines of the first display panel;
a first gate driving unit configured to sequentially supply a scan pulse to first gate lines of the first display panel;
a second drive integrated circuit configured to convert pixel data of the right-eye image into second data voltages and supply the second data voltages to second data lines of the second display panel;
a second gate driving unit configured to sequentially supply a scan pulse to second gate lines of the second display panel;
a first eyepiece disposed on the first display panel; and
a second eyepiece disposed on the second display panel,
wherein each of the first display panel and the second display panel includes:
a first display area including a first plurality of sub-pixels disposed on a substrate and a second display area including a second plurality of sub-pixels disposed on the substrate, the second display area surrounding the first display area;
a light emitting layer disposed on the substrate;
a color filter layer disposed on the light emitting layer; and
a plurality of condensing lenses disposed on the color filter layer in the second display area,
wherein the plurality of condensing lenses respectively correspond to emission areas of the second plurality of sub-pixels,
wherein a central axis of each of the plurality of condensing lenses is misaligned with a central axis of a corresponding emission area among the emission areas,
wherein a size of the first eyepiece is smaller than a size of the first display panel, and
wherein a size of the second eyepiece is smaller than a size of the second display panel.

20. The personal immersion device of claim 19, wherein light emitted from the plurality of condensing lenses of the first display panel is collected into the first eyepiece, and
wherein light emitted from the plurality of condensing lenses of the second display panel is collected into the second eyepiece.

21. A display panel comprising:
a first type of sub-pixel disposed in a first display area of a substrate;
a second type of sub-pixel disposed in a second display area of the substrate; and
a lens disposed on the second type of sub-pixel in the second display area,
wherein the lens of the second type of sub-pixel is shifted closer to the first display area than an emission area of the second type of sub-pixel.

22. The display panel of claim 21, wherein the lens includes an overlapping portion that overlaps with the emission area and a non-overlapping portion that does not overlap with the emission area, and
wherein an area of the overlapping portion of the lens is greater than an area of the non-overlapping portion of the lens.

23. The display panel of claim 21, wherein the first display area has a circular shape or a square shape in a plan view, and
wherein the second display area is divided into a plurality of second display regions that are disposed around the first display area.

24. The display panel of claim 23, wherein the plurality of second display regions include a plurality of sub-pixels of the second type, and
wherein lenses corresponding to the plurality of sub-pixels in the plurality of second display regions are shifted in different directions relative to corresponding emission areas of the plurality of sub-pixels.

25. The display panel of claim 23, wherein outer lenses corresponding to outer sub-pixels among the plurality of sub-pixels that are located farther away from the first display area than inner lenses corresponding to inner sub-pixels among the plurality of sub-pixels that are located closer to the first display area than the outer lenses are shifted by greater distances away from outer corresponding emission areas corresponding to the outer lenses than the inner lenses and inner emission areas corresponding to the inner lenses.

26. The display panel of claim 21, wherein the lens has a semi-cylindrical shape, or
wherein the lens has a rectangular shape in a plan view.

27. The display panel of claim 21, further comprising:
an inner sub-pixel of the second type disposed in the second display area, the inner sub-pixel being adjacent to the first display area;
an outer sub-pixel of the second type disposed in the second display area, the outer sub-pixel being farther away from the first display area than the inner sub-pixel;
a first lens disposed on the inner sub-pixel, the first lens being shifted closer towards the first display area than a first emission area of the inner sub-pixel by a first distance; and
a second lens disposed on the outer sub-pixel, the second lens being shifted closer towards the first display area than a second emission area of the outer sub-pixel by a second distance,
wherein the second distance is greater than the first distance.
